(19) United States
(12) Patent Application Publication
(10) Pub. No.: US 2026/0182020 A1
(43) Pub. Date: Jun. 25, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Cheng-Ting CHUNG, Hsinchu City (TW); Hou-Yu CHEN, Zhubei City (TW)

(21) Appl. No.: 19/001,124

(22) Filed: Dec. 24, 2024

(51) Int. Cl. H10D 84/85; H10D 84/01

(52) U.S. Cl. CPC H10D 84/856; H10D 84/0167; H10D 84/017; H10D 84/0186; H10D 84/0188; H10D 84/851

(57) ABSTRACT

A semiconductor structure is provided. The semiconductor structure a bottom transistor and a top transistor above the bottom transistor. The bottom transistor includes a first nanostructure, and a first bottom source/drain feature and a second bottom source/drain feature adjoining the first nanostructure. The top transistor includes a second nanostructure, and a first top source/drain feature and a second top source/drain feature adjoining the second nanostructure. The semiconductor structure further includes a first frontside contact structure on a top surface of the first top source/drain feature, a backside contact structure on a bottom surface of the first bottom source/drain feature, and a non-metallic structure on a bottom surface of the second bottom source/drain feature. The non-metallic structure has a different material composition than a material composition of the backside contact structure.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, complementary FET (CFET) have been introduced. In a CFET structure, nMOS and pMOS devices are stacked on top of each other, so that the effective channel width of the resulting device may be further maximized. However, integration of fabrication of the CFET devices can be challenging.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIG. 2 is a layout of a semiconductor structure, in accordance with some embodiments.

FIGS. 3A-1 and 3A-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 3B-1 and 3B-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 3C-1 and 3C-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 3D-1 and 3D-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 3E-1 and 3E-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 3F-1, 3F-2 and 3F-3 are cross-sectional views the of formation of a semiconductor structure at one of the intermediate stages corresponding to line X-X, line Y1-Y1 and line Y2-Y2 of FIG. 2, in accordance with some embodiments of the disclosure

FIGS. 3G-1, 3G-2 and 3G-3 are cross-sectional views the of formation of a semiconductor structure at one of the intermediate stages corresponding to line X-X, line Y1-Y1 and line Y2-Y2 of FIG. 2, in accordance with some embodiments of the disclosure

FIGS. 3H-1, 3H-2 and 3H-3 are cross-sectional views the of formation of a semiconductor structure at one of the intermediate stages corresponding to line X-X, line Y1-Y1 and line Y2-Y2 of FIG. 2, in accordance with some embodiments of the disclosure

FIGS. 3I-1, 3I-2 and 3I-3 are cross-sectional views the of formation of a semiconductor structure at one of the intermediate stages corresponding to line X-X, line Y1-Y1 and line Y2-Y2 of FIG. 2, in accordance with some embodiments of the disclosure

FIGS. 3J-1, 3J-2 and 3J-3 are cross-sectional views the of formation of a semiconductor structure at one of the intermediate stages corresponding to line X-X, line Y1-Y1 and line Y2-Y2 of FIG. 2, in accordance with some embodiments of the disclosure

FIGS. 3K-1, 3K-2 and 3K-3 are cross-sectional views the of formation of a semiconductor structure at one of the intermediate stages corresponding to line X-X, line Y1-Y1 and line Y2-Y2 of FIG. 2, in accordance with some embodiments of the disclosure

FIG. 3L illustrates a modification of the semiconductor structure of FIG. 3K-2.

FIGS. 4A-1 and 4A-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 4B-1 and 4B-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 4C-1 and 4C-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 4D-1 and 4D-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 4E-1 and 4E-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 4F-1 and 4F-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 4G-1, 4G-2 and 4G-3 are cross-sectional views the of formation of a semiconductor structure at one of the intermediate stages corresponding to line X-X, line Y1-Y1 and line Y2-Y2 of FIG. 2, in accordance with some embodiments of the disclosure

FIGS. 4H-1, 4H-2 and 4H-3 are cross-sectional views the of formation of a semiconductor structure at one of the intermediate stages corresponding to line X-X, line Y1-Y1 and line Y2-Y2 of FIG. 2, in accordance with some embodiments of the disclosure

FIGS. 4I-1, 4I-2 and 4I-3 are cross-sectional views the of formation of a semiconductor structure at one of the intermediate stages corresponding to line X-X, line Y1-Y1 and line Y2-Y2 of FIG. 2, in accordance with some embodiments of the disclosure

FIGS. 5A-1 and 5A-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 5B-1 and 5B-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 5C-1 and 5C-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 5D-1 and 5D-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 5E-1 and 5E-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 5F-1 and 5F-2 are cross-sectional views illustrating the formation of a semiconductor structure at one of the intermediate stages corresponding to line X-X and line Y1-Y1 or Y2-Y2 of FIG. 2, in accordance with some embodiments of the disclosure.

FIGS. 5G-1, 5G-2 and 5G-3 are cross-sectional views the of formation of a semiconductor structure at one of the intermediate stages corresponding to line X-X, line Y1-Y1 and line Y2-Y2 of FIG. 2, in accordance with some embodiments of the disclosure

FIGS. 5H-1, 5H-2 and 5H-3 are cross-sectional views the of formation of a semiconductor structure at one of the intermediate stages corresponding to line X-X, line Y1-Y1 and line Y2-Y2 of FIG. 2, in accordance with some embodiments of the disclosure

FIGS. 5I-1, 5I-2 and 5I-3 are cross-sectional views the of formation of a semiconductor structure at one of the intermediate stages corresponding to line X-X, line Y1-Y1 and line Y2-Y2 of FIG. 2, in accordance with some embodiments of the disclosure

FIGS. 5J-1, 5J-2 and 5J-3 are cross-sectional views the of formation of a semiconductor structure at one of the intermediate stages corresponding to line X-X, line Y1-Y1 and line Y2-Y2 of FIG. 2, in accordance with some embodiments of the disclosure

FIGS. 5K-1, 5K-2 and 5K-3 are cross-sectional views the of formation of a semiconductor structure at one of the intermediate stages corresponding to line X-X, line Y1-Y1 and line Y2-Y2 of FIG. 2, in accordance with some embodiments of the disclosure

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of semiconductor structures and methods for forming the same are provided. The semiconductor structures may include a complementary field-effect transistor (CFET) device, the CFET device includes a bottom transistor and a top transistor. The frontside surfaces of the first and second source/drain features of the top transistor are connected to frontside contact structures, and the backside surface of the first source/drain feature of the bottom transistor is connected to the backside contact structure. The second source/drain feature of the bottom transistor is connected to the frontside contact structure. No contact structure is formed on the backside surface of the second source/drain feature of the bottom transistor, and thus the overall cell capacitance of the CFET device may be reduced. Therefore, the performance of the resulting semiconductor device may be enhanced, e.g., with faster speed and lower power consumption.

In addition, in some embodiments, a dielectric isolation feature may be formed between the second source/drain feature of the bottom transistor and a lower fin element, and thus the overall cell capacitance of the CFET device may be further reduced.

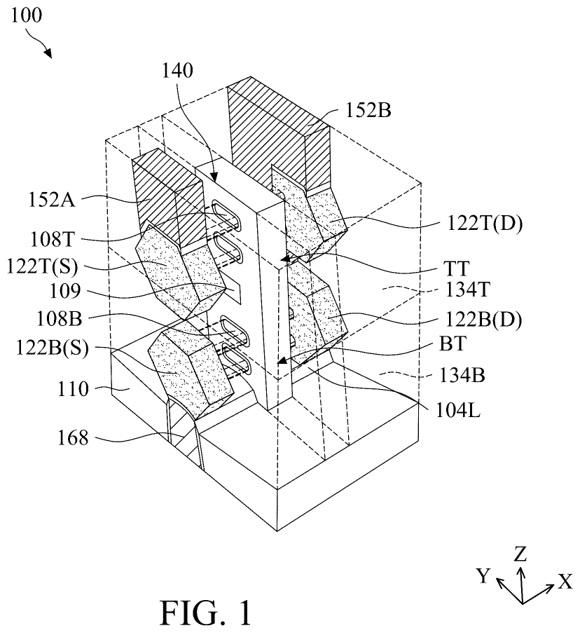

FIG. 1 is a perspective view of a semiconductor structure 100, in accordance with some embodiments.

The semiconductor structure 100 includes a fin element 104L, an isolation structure 110 surrounding the fin element 104L, a bottom transistor BT above the fin element 104L, and a top transistor TT directly above the bottom transistor BT, in accordance with some embodiments. Both the top transistor TT and the bottom transistor BT are nanostructure transistors such as GAA transistors, in accordance with some embodiments.

For a better understanding of the semiconductor structure, X-Y-Z coordinate reference is provided in the figures of the present disclosure. The X-axis and the Y-axis are generally orientated along the lateral (or horizontal) directions that are parallel to the main surface of the substrate. The Y-axis is transverse (e.g., substantially perpendicular) to the X-axis. The Z-axis is generally oriented along the vertical direction that is perpendicular to the main surface of the substrate (or the X-Y plane).

In some embodiments, the bottom transistor BT is a p-channel FET, and the top transistor TT is an n-channel FET. In some other embodiments, the bottom transistor BT is an n-channel FET, and the top transistor TT is a p-channel FET. The semiconductor structure 100 may be used to form STD cells e.g., CMOS inverter, NAND, NOR, AND, OR, Flip-Flop, and/or SCAN cell regions, and/or memory cells such as SRAM.

The bottom transistor BT includes a plurality of nanostructures 108B, bottom source/drain features 122B (including 122B(S) for the source terminal and 122B(D) for the drain terminal) adjoining the nanostructures 108B, and the bottom portion of a gate stack 140 wrapped around the nanostructures 108B, in accordance with some embodiments. The top transistor TT includes a plurality of nanostructures 108T, top source/drain features 122T (including the 122T(S) for the source terminal and 122T(D) for the drain terminal) adjoining the nanostructures 108T, and the top portion of the gate stack 140 wrapped around the nanostructures 108T, in accordance with some embodiments. In some embodiments, an insulating layer 109 is formed between the nanostructures 108B and the nanostructures 108T.

The semiconductor structure 100 further includes a frontside contact structure 152A landing on the top source/drain feature 122T(S) and a frontside contact structure 152B landing on the top source/drain feature 122T(D) and penetrates through the top source/drain feature 122T(D) and land on the bottom source/drain feature 122B(D), in accordance with some embodiments. The semiconductor structure 100 further includes a backside contact structure 168 which is formed in or through the fin element 104L and abuts the backside surface of the bottom source/drain feature 122B(S).

In some embodiments where the bottom transistor BT is a p-channel FET, and the top transistor TT is an n-channel FET, the top source/drain features 122T(S) of the top transistor TT is electrically connected to a Vss frontside power rail formed in a frontside metal layer (not shown) through the frontside contact structure 152A and a via (not shown) on the frontside contact structure 152A. The source/drain features 122B(S) of the bottom transistor BT are electrically connected to a Vdd backside power rail formed in the backside metal layer (not shown) through the backside contact structure 168.

The interlayer dielectric layers 134T and 134B are formed to cover the top source/drain features 122T and the bottom source/drain features 122B, respectively. The top source/drain features 122T(S) and the bottom source/drain features 122B(S) are electrically isolated from each other by the interlayer dielectric layer 134B, in accordance with some embodiments. In some other embodiments, the source/drain features 122B(S) of the top transistor TT may be electrically connected to a Vss backside power rail. In some embodiments, the source/drain features 122T(D) and 122B(D) are electrically connected to each other through the frontside contact structure 152B, and are electrically connected to a signal line in a frontside metal layer (not shown).

The nanostructures 108B/108T extend between the source/drain features 122B/122T in the X direction, in accordance with some embodiments. The nanostructures 108B and 108T function as the channels of the transistors BT and TT, in accordance with some embodiments. Although two nanostructures 108B and two nanostructures 108T are shown in FIG. 1, the number is not limited to two, and can be one or three, and is less than 10. The X direction may also be referred to as the channel-extending direction. The current of the resulting semiconductor device (i.e., nanostructure transistor) flows in the X direction through the channels. It is noted that in the present disclosure, source/drain region(s) or source/drain feature(s) may refer to a source or a drain, individually or collectively dependent upon the context.

The gate stack 140 is formed with longitudinal axes parallel to the Y direction and extending across and/or surrounding the nanostructures 108B and 108T, in accordance with some embodiments. The Y direction may also be referred to as a gate-routing direction, in accordance with some embodiments. In some embodiments, the top portion of the gate stack 140 for the top transistor TT is physically connected to the bottom portion of the gate stack 140 for the bottom transistor BT. In some embodiments, the top portion of the gate stack 140 for the top transistor TT is electrically connected to the bottom portion of the gate stack 140 for the bottom transistor BT. In some other embodiments, the top portion of the gate stack 140 for the top transistor TT is physically and electrically isolated from the bottom portion of the gate stack 140 for the bottom transistor BT.

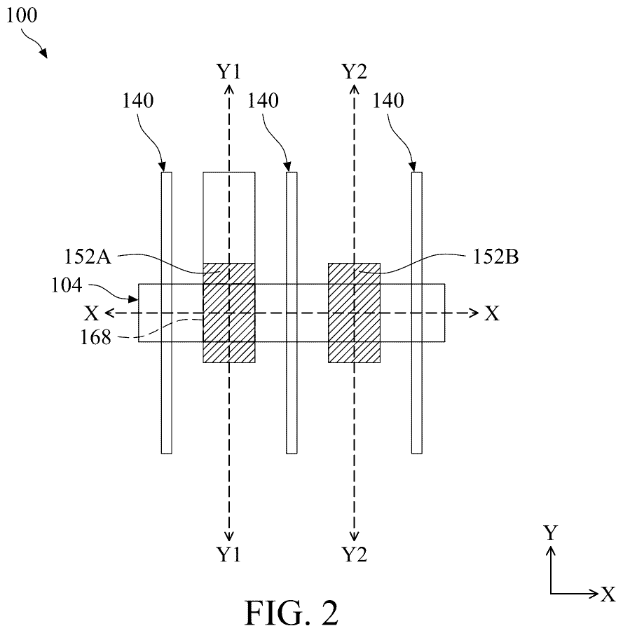

FIG. 2 illustrates the layout of the semiconductor structure 100, in accordance with some embodiments.

The semiconductor structure 100 includes an active region 104, and gate stacks 140 across the active region 104, in accordance with some embodiments. The active region 104 extends in the X direction, in accordance with some embodiments. The active region 104 includes a lower fin element and nanostructures (e.g., nanostructures 108B and 108T shown in FIG. 1) over the lower fin element, in accordance with some embodiments. The gate stacks 140 extend in the Y direction and across the lower fin elements, and wrap around the nanostructures of the active region 104, in accordance with some embodiments. The gate stacks 140 are combined with the nanostructures of the active region 104 to form nanostructure transistors (e.g., bottom transistor BT and top transistor TT in FIG. 1), in accordance with some embodiments.

Frontside contact structures 152A and 152B are disposed on the source/drain regions of the active region 104, in accordance with some embodiments. The contact structures 152A and 152B are electrically connected to a frontside metal layer M1 where the contact structure 152A serves as a Vdd/Vss node and is electrically connected to a frontside power supply line through a via, and the contact structure 152B serves as a non-Vdd/Vss node and is electrically connected to a signal line through a via, in accordance with some embodiments. The gate stack 140 is electrically connected to the frontside metal layer M1 through a via, in accordance with some embodiments.

A backside contact structure 168 is disposed on the backside of the source/drain region of the active region 104, in accordance with some embodiments. The backside contact structure 168 serves as a Vdd/Vss node and is electrically connected to a backside power rail.

FIG. 2 further illustrates reference cross-sections that are used in later figures. Cross-section X-X is in a plane parallel to the longitudinal axis (X direction) of the active region 104 and through the active region 104, in accordance with some embodiments. Cross-section Y1-Y1 is in a plane parallel to the longitudinal axis (Y direction) of the gate stack 140 and across the Vdd/Vss nodes (or source terminal) of the source/drain region of the active region 104, in accordance with some embodiments. Cross-section Y2-Y2 is in a plane parallel to the longitudinal axis (Y direction) of the gate stack 140 and across the non-Vdd/Vss nodes (or drain terminal) of the source/drain region of the active region 104, in accordance with some embodiments.

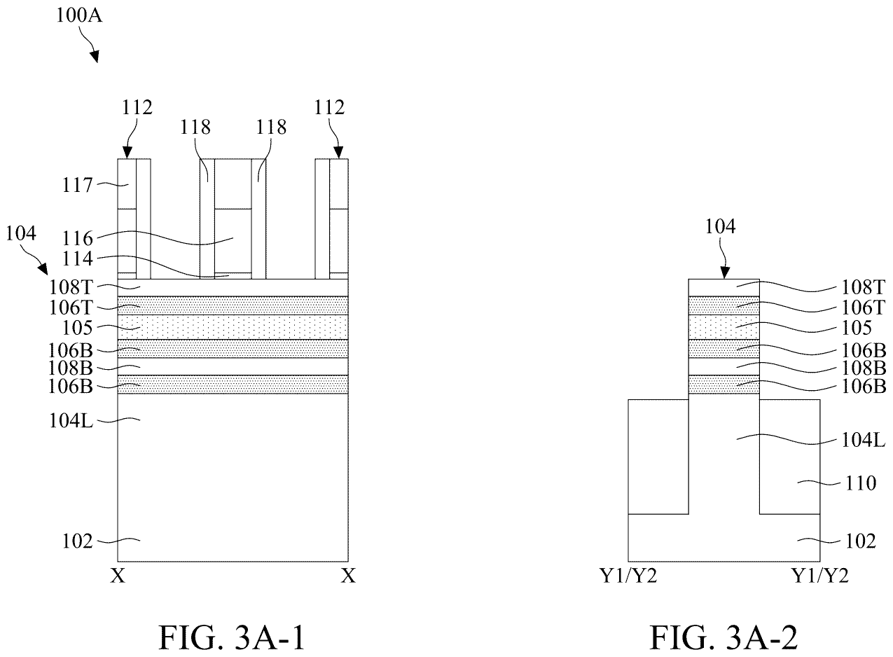

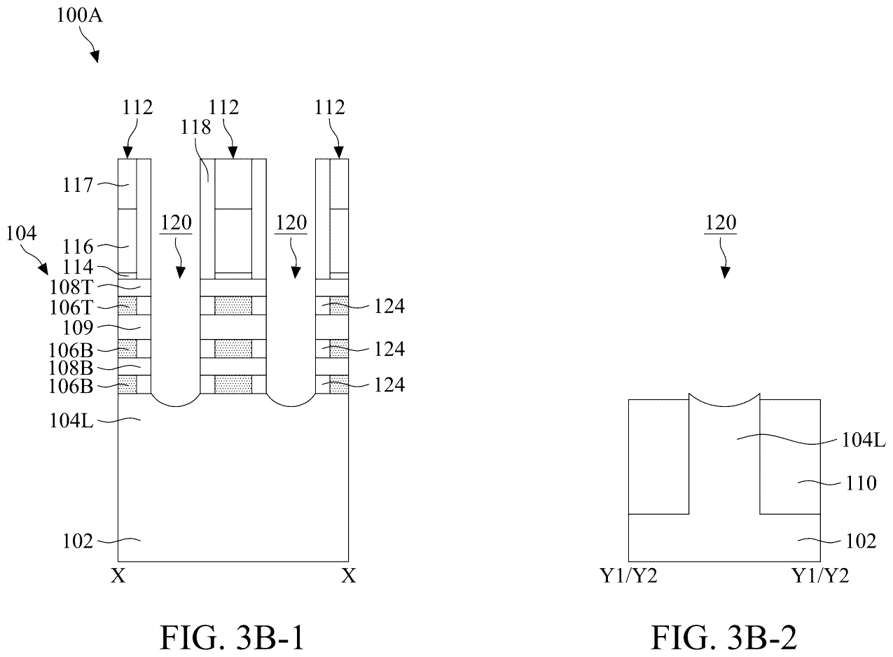

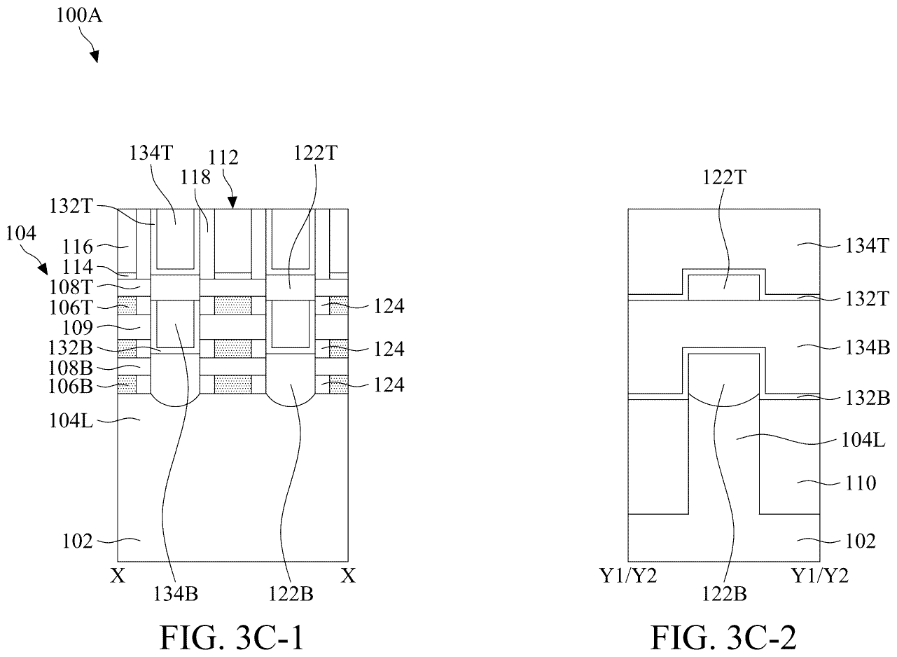

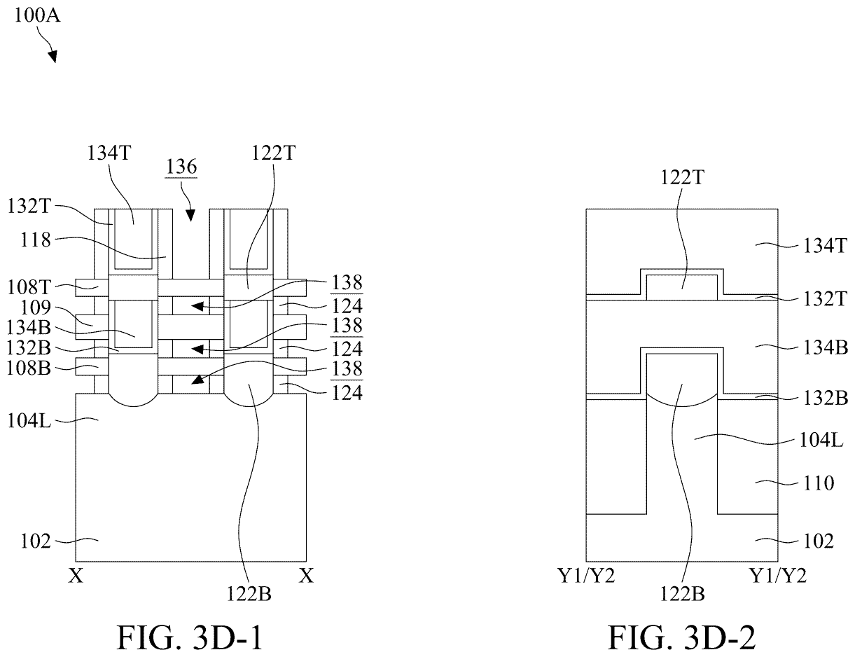

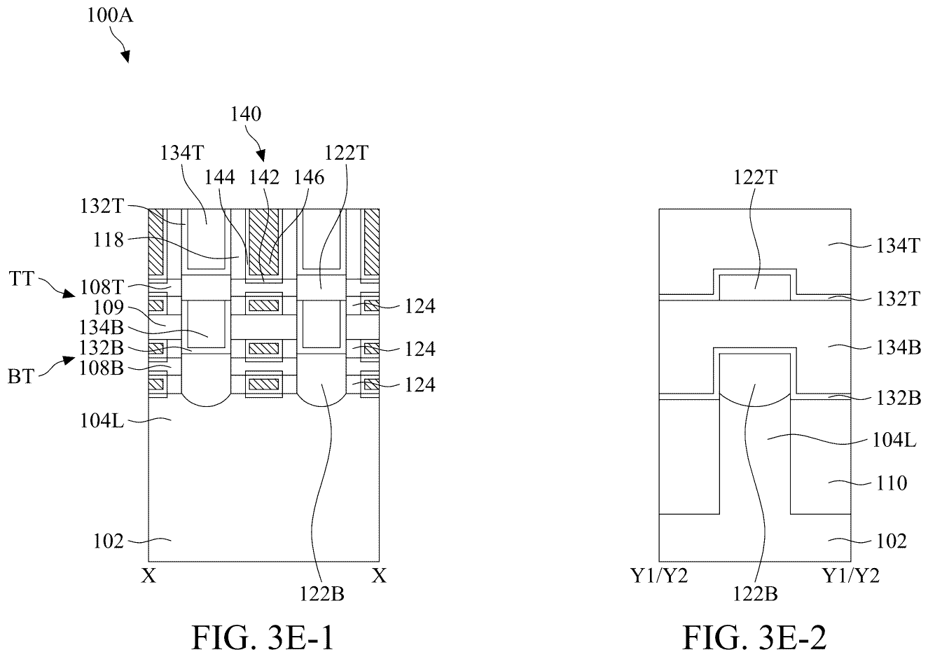

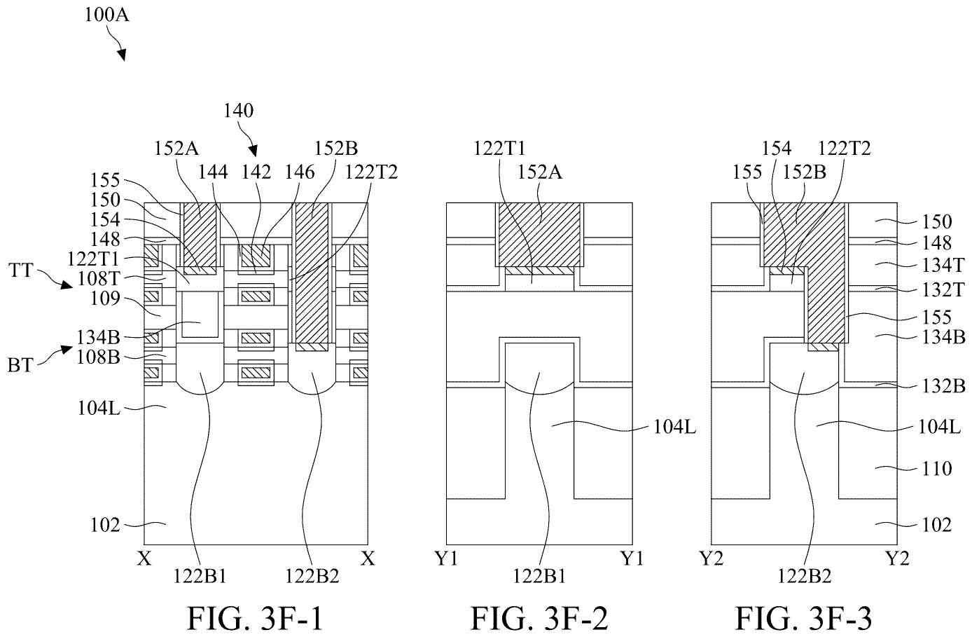

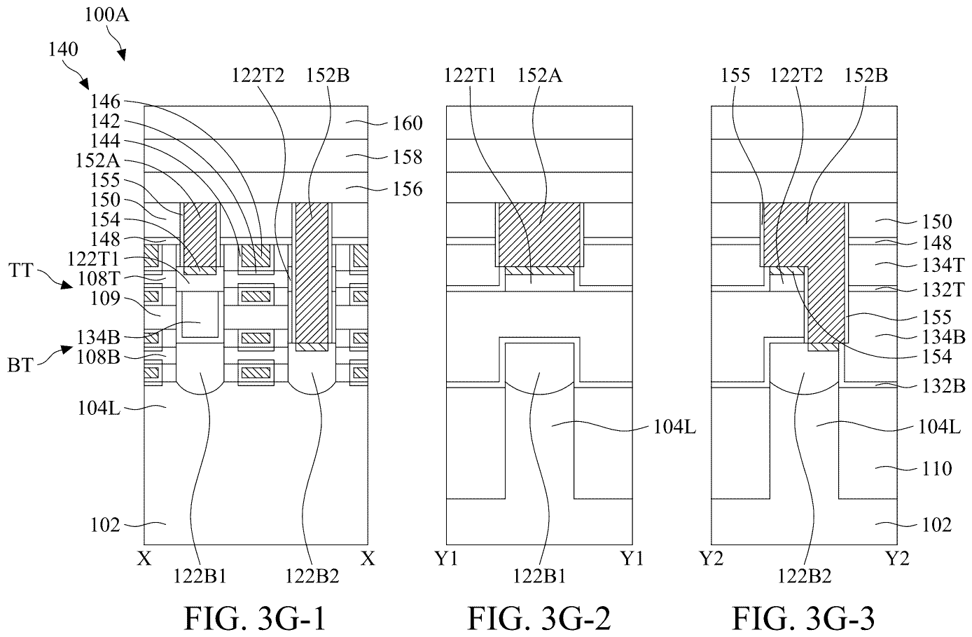

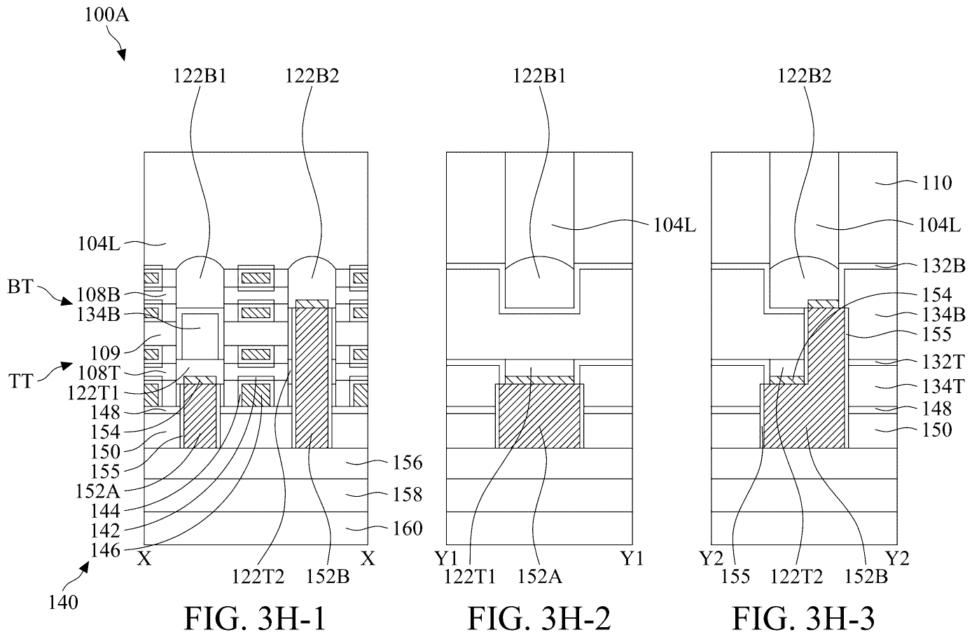

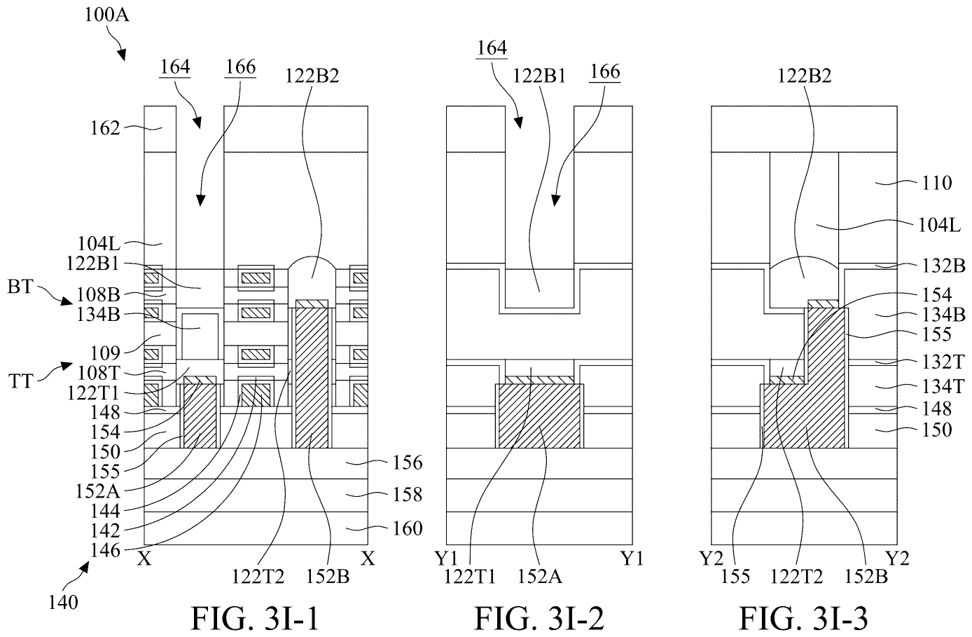

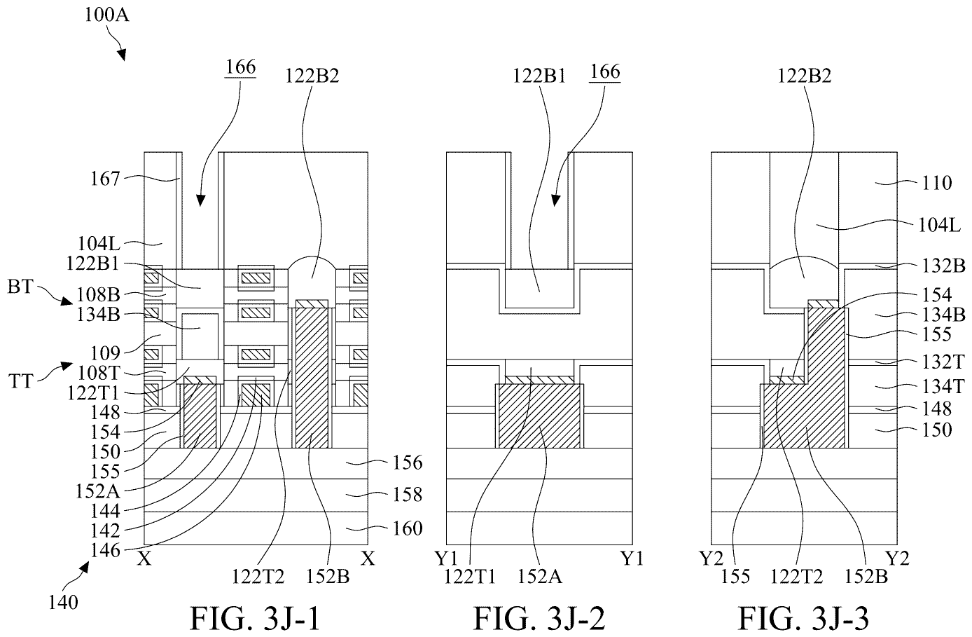

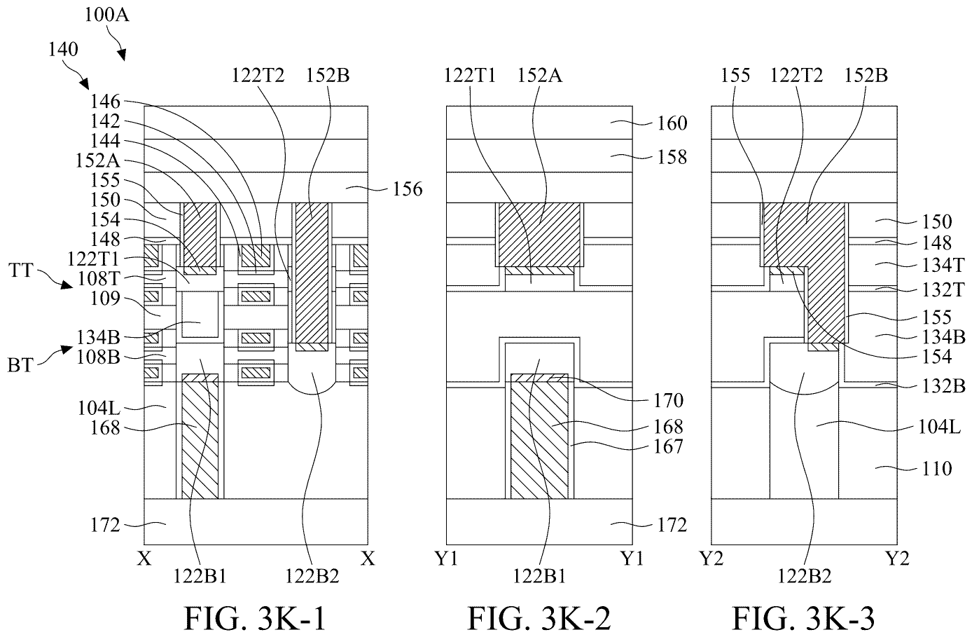

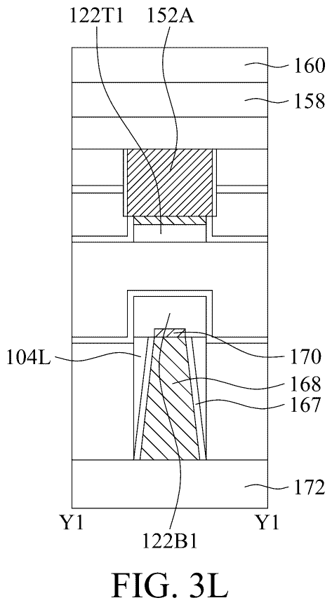

FIGS. 3A-1 through 3K-3 are cross-sectional views illustrating the formation of the semiconductor structure of FIG. 2 at various intermediate stages, in accordance with some embodiments of the disclosure. FIGS. 3A-1, 3B-1, 3C-1, 3D-1, 3E-1, 3F-1, 3G-1, 3H-1, 3I-1, 3J-1 and 3K-1 correspond to line X-X of FIG. 2. FIGS. 3A-2, 3B-2, 3C-2, 3D-2 and 3E-2 correspond to line Y1 -Y1 or line Y2 -Y2 of FIG. 2. FIGS. 3F-2, 3G-2, 3H-2, 3I-2, 3J-2 and 3K-2 correspond to line Y1 -Y1 of FIG. 2. FIGS. 3F-3, 3G-3, 3H-3, 3I-3, 3J-2 and 3K-2 correspond to line Y2 -Y2 of FIG. 2.

FIGS. 3A-1 and 3A-2 illustrate a semiconductor structure 100A after the formation of an active region 104, an isolation structure 110, dummy gate structures 112 and gate spacer layer 118, in accordance with some embodiments.

The semiconductor structure 100A includes a substrate 102 and an active region 104 formed over the substrate 102, as shown in FIGS. 3A-1 and 3A-2, in accordance with some embodiments. The semiconductor structure 100A is used to form a CFET device in which n-type devices and p-type devices are stacked on top of each other. The frontside of the semiconductor structure 100A (or the substrate 102) faces upward, in accordance with some embodiments.

The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

In some embodiments, the active region 104 extends in the X direction. That is, the active region 104 has a longitudinal axis parallel to the X direction, in accordance with some embodiments. The formation of the active region 104 includes forming a stack over the substrate 102, in accordance with some embodiments. The stack is a multi-layered structure which includes first semiconductor layers 106B and 106T, second semiconductor layers 108B and 108T, and a middle layer 105, in accordance with some embodiments.

In some embodiments, the first semiconductor layers 106B and 106T are made of a first semiconductor material, and the second semiconductor layers 108B and 108T are made of a second semiconductor material with a different composition than the first semiconductor material. The first semiconductor material for the first semiconductor layers 106B and 106T has a different lattice constant than the second semiconductor material for the second semiconductor layers 108B and 108T, in accordance with some embodiments. In some embodiments, the first semiconductor material and the second semiconductor material have different oxidation rates and/or etching selectivity.

In some embodiments, the first semiconductor layers 106B and 106T are made of SiGe, where the percentage of germanium (Ge) in the SiGe is in a range from about 20 atomic % to about 50 atomic %, and the second semiconductor layers 108B and 108T are made of pure or substantially pure silicon. In some embodiments, the first semiconductor layers 106B and 106T are Si₁₋ₓGeₓ, where x is more than about 0.3, or Ge (x=1.0) and the second semiconductor layers 108B and 108T are Si or Si_{1-y}Gey, where y is less than about 0.4, and x>y.

In some embodiments, the second semiconductor layer 108B and the second semiconductor layer 108T are made of the same material, such as Si. In some embodiments, the second semiconductor layer 108B and the second semiconductor layer 108T are made of different materials depending on the overall performance of the resulting CFET devices, for example, the second semiconductor layers 108B are made of SiGe, and the second semiconductor layers 108T are made of Si.

In some embodiments, the middle layer 105 is made of the same material as the first semiconductor layers 106B and 106T, e.g., SiGe. In some embodiments, the middle layer 105 is a SiGe layer with a higher germanium concentration than the first semiconductor layers 106B and 106T.

The stack is defined as a bottom device region and a top device region above the bottom device region, where the middle layer 105 is interposed between the bottom device region and the top device region, in accordance with some embodiments. The bottom device region includes the semiconductor layers 106B and 108B while the top device region includes the semiconductor layers 106T and 108T, in accordance with some embodiments.

In some embodiments, the bottom device region is used to form p-type devices (e.g., p-channel nanostructure transistors), and the top device region is used to form n-type devices (e.g., n-channel nanostructure transistors). In some other embodiments, the bottom device region is used to form n-type devices (e.g., n-channel nanostructure transistors), and the top device region is used to form p-type devices (e.g., p-channel nanostructure transistors).

The layers 106B, 106T, 108B and 108T and 105 of the stack are depositing using an epitaxial growth process, in accordance with some embodiments. The epitaxial growth process may be molecular beam epitaxy (MBE), metal organic chemical vapor deposition (MOCVD), or vapor phase epitaxy (VPE), or another suitable technique. The middle layer 105 is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

The number of the first semiconductor layers 106T and 106B and the second semiconductor layers 108T and 108B are not limited thereto. For example, the number of the second semiconductor layers 108T and the number of the second semiconductor layers 108B may be less than 10, e.g., 2-4, and the first semiconductor layers 106B are alternatingly stacked with the second semiconductor layers 108B, and the first semiconductor layers 106T are alternatingly stacked with the second semiconductor layers 108T. In addition, the number of the second semiconductor layers 108T may be different from the number of the second semiconductor layers 108B.

In some embodiments, the thickness of each of first semiconductor layers 106B and 106T is in a range from about 6 nm to about 16 nm. In some embodiments, the thickness of each of the second semiconductor layers 108B and 108T is in a range from about 4 nm to about 8 nm.

The first semiconductor layers 106B and 106T are configured as sacrificial layers and will be removed to form gaps to accommodate gate materials, in accordance with some embodiments. The second semiconductor layers 108B and 108T will form nanostructures (e.g., nanowires or nanosheets) that laterally extend between source/drain features and serve as the channel for the resulting semiconductor device (such as a nanostructure transistor), in accordance with some embodiments. As the term is used herein, “nanostructures” refers to semiconductor layers that have cylindrical shape, bar shape and/or sheet shape. A gate stack (not shown) will be formed across and wrap around the nanostructures, in accordance with some embodiments.

The formation of the active region 104 further includes patterning the stack and underlying substrate 102 using photolithography and etching processes, thereby forming trenches and an active region 104 protruding from between trenches, in accordance with some embodiments. The portion of the substrate 102 protruding from between the trenches serves as a lower fin element 104L of the active region 104, in accordance with some embodiments. The remainder of the stack serves as the upper fin element of the active region 104, in accordance with some embodiments. In some embodiments, the active region 104 may be referred to a fin or a fin structure. Although one active region 104 is shown in FIGS. 3A-1 and 3A-2, the number of the active region 104 is not limited thereto, and may depend on the performance and design demands of the resulting semiconductor device.

An isolation structure 110 is formed to surround the lower fin element 104L of the active region 104, as shown in FIGS. 3A-2, in accordance with some embodiments. The isolation structure 110 is configured to electrically isolate neighboring active regions 104 and is also referred to as shallow trench isolation (STI) feature, in accordance with some embodiments.

The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active region 104, in accordance with some embodiments. The planarization may be chemical mechanical polishing (CMP), an etching back process, or a combination thereof. The insulating material is then recessed by an etching process (such as dry plasma etching and/or wet chemical etching) to expose the sidewalls of the upper fin element of the active region 104, in accordance with some embodiments. The remaining insulating material serves as the isolation structure 110, in accordance with some embodiments.

Dummy gate structures 112 are formed across the active region 104 and the isolation structure 110, as shown in FIGS. 3A-1, in accordance with some embodiments. The dummy gate structures 112 are configured as sacrificial structures and will be replaced with the final gate stacks, in accordance with some embodiments. In some embodiments, the dummy gate structures 112 extend in the Y direction. That is, the dummy gate structures 112 have longitudinal axes parallel to the Y direction, in accordance with some embodiments. The dummy gate structures 112 surround the channel regions of the active region 104, in accordance with some embodiments. Each of the dummy gate structures 112 includes a dummy gate dielectric layer 114 and a dummy gate electrode layer 116 formed over the dummy gate dielectric layer 114, as shown in FIG. 3A-1, in accordance with some embodiments.

In some embodiments, the dummy gate dielectric layer 114 is conformally formed along the upper fin element of the active region 104. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, HfAlO. In some embodiments, the dielectric material is deposited using ALD, CVD, thermal oxidation, physical vapor deposition (PVD), another suitable technique, or a combination thereof.

In some embodiments, the dummy gate electrode layer 116 is made of semiconductor material such as polysilicon or poly-silicon germanium. In some embodiments, the material for the dummy gate electrode layer 116 is deposited using CVD, ALD, another suitable technique, or a combination thereof.

In some embodiments, the formation of the dummy gate structures 112 includes globally and conformally depositing a dielectric material for the dummy gate dielectric layer 114 over the semiconductor structure 100A, depositing a material for the dummy gate electrode layer 116 over the dielectric material, planarizing the material for the dummy gate electrode layer 116, and patterning the material for the dummy gate electrode layer 116 and the dielectric material into the dummy gate structures 112.

The patterning process includes forming a patterned hard mask layer 117 over the material for the dummy gate electrode layer 116, in accordance with some embodiments. The patterned hard mask layer corresponds to and overlaps the channel regions of the active region 104, in accordance with some embodiments. The materials for the dummy gate dielectric layer 114 and the dummy gate electrode layer 116, uncovered by the patterned hard mask layer, are etched away until the active region 104 and the top surface of the isolation structure 110 are exposed, in accordance with some embodiments.

Gate spacer layers 118 are formed along opposite sidewalls of the dummy gate structures 112, as shown in FIG. 3A-1, in accordance with some embodiments. The gate spacer layers 118 extend in the Y direction and across the active region 104 and the isolation structure 110, in accordance with some embodiments. The gate spacer layers 118 are used to offset the subsequently formed source/drain features and separate the source/drain features from the gate structure, in accordance with some embodiments.

In some embodiments, the formation of the gate spacer layers 118 includes globally and conformally depositing a dielectric material over the semiconductor structure 100A using atomic layer deposition (ALD), CVD (such as LPCVD, PECVD, HDP-CVD and HARP), another suitable method, and/or a combination thereof, followed by an anisotropic etching process. In some embodiments, the etching process is performed without an additional photolithography process. In some embodiments, the gate spacer layers 118 may be silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. The vertical portions of the dielectric material left remaining on the opposite sides of the dummy gate structures 112 serve as the gate spacer layers 118, in accordance with some embodiments.

FIGS. 3B-1 and 3B-2 illustrate the semiconductor structure 100A after the formation of source/drain recesses 120 and inner spacer layers 124, in accordance with some embodiments.

An etching process is performed to recess the source/drain regions of the active region 104, thereby forming source/drain recesses 120, as shown in FIGS. 3B-1 and 3B-3, in accordance with some embodiments. The etching process may be an anisotropic etching process such as dry plasma etching, an isotropic etching process such as dry chemical etching, remote plasma etching or wet chemical etching, and/or a combination thereof.

The gate spacer layers 118 and the dummy gate structures 112 may serve as etch masks such that the source/drain recesses 120 are formed self-aligned on opposite sides of the dummy gate structures 112, in accordance with some embodiments. The source/drain recesses 120 may extend a distance into the lower fin element 104L, in accordance with some embodiments.

An etching process is performed to remove the middle layer 105, thereby forming a gap, and then an insulating layer 109 is formed in the gap, as shown in FIG. 3B-1, in accordance with some embodiments. In some embodiments, the insulating layer 109 is made of dielectric material such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof.

In some embodiments, the insulating layer 109 is formed by depositing a dielectric material to fill the gap, and then etching away the dielectric material outside the gap. In some embodiments, the deposition process includes ALD, CVD (such as PECVD, LPCVD or HARP), another suitable technique, or a combination thereof. In some embodiments, the etching back process includes an anisotropic etching process such as dry plasma etching, an isotropic etching process such as dry chemical etching, remote plasma etching or wet chemical etching, or a combination thereof.

An etching process is performed to laterally recess, from the source/drain recesses 120, the first semiconductor layers 106B and 106T of the active region 104, thereby forming notches, and then inner spacer layers 124 are formed in the notches, as shown in FIG. 3B-1, in accordance with some embodiments. The inner spacer layers 124 abut the recessed side surfaces of the first semiconductor layers 106B and 106T, in accordance with some embodiments. The inner spacer layers 124 may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacer layers 124 are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. In some embodiments, the inner spacer layers 124 are formed by depositing a dielectric material to fill the notches, and then etching away the dielectric material outside the notches. In some embodiments, the deposition process includes ALD, CVD (such as PECVD, LPCVD or HARP), another suitable technique, or a combination thereof. In some embodiments, the etching back process includes an anisotropic etching process such as dry plasma etching, an isotropic etching process such as dry chemical etching, remote plasma etching or wet chemical etching, or a combination thereof.

FIGS. 3C-1 and 3C-2 illustrate the semiconductor structure 100A after the formation of bottom source/drain features 122B, top source/drain features 122T, contact etching stop layers 132B and 132T, and first interlayer dielectric layers 134B and 134T, in accordance with some embodiments.

Bottom source/drain features 122B are grown from the exposed side surfaces of the second semiconductor layers 108B and the exposed top surface of the lower fin element 104L in the source/drain recesses 120 using an epitaxial growth process, as shown in FIGS. 3C-1 and 3C-2, in accordance with some embodiments. The epitaxial growth process may be MBE, MOCVD, or VPE, or another suitable technique. In some embodiments, a spacer layer may be formed to cover the exposed side surfaces of the second semiconductor layers 108T to prevent epitaxial material formed on second semiconductor layers 108T. After the bottom source/drain features 122B are formed, the spacer layer may be removed.

In some embodiments, the bottom source/drain features 122B are made of any suitable semiconductor material for n-type semiconductor devices or p-type semiconductor devices. In some embodiments, the bottom source/drain features 122B are doped. The concentration of the dopant in the bottom source/drain features 122B in a range from about 1×10¹⁹ cm⁻³ to about 6×10²¹ cm^{31 3}.

In some embodiments where the bottom device region of the active region 104 is to be formed as p-type devices (e.g., p-channel nanostructure transistors), the bottom source/drain features 122B are made of semiconductor material such as SiGe, Si, GaAs, another suitable semiconductor material, or a combination thereof. In some embodiments, the bottom source/drain features 122B are doped with the p-type dopant during the epitaxial growth process. For example, the p-type dopant may be boron (B) or BF₂. For example, the bottom source/drain features 122B may be the epitaxially grown SiGe doped with boron (B) to form silicon germanium:boron (SiGe:B) source/drain feature.

A contact etching stop layer 132B is formed over the semiconductor structure 100A to cover the bottom source/drain features 122B, as shown in FIGS. 3C-1 and 3C-2, in accordance with some embodiments. In some embodiments, the contact etching stop layer 132B is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, dielectric material for the contact etching stop layer 132B is globally and conformally deposited over the semiconductor structure 100A using CVD (such as LPCVD, PECVD, HDP-CVD, or HARP), ALD, another suitable method, or a combination thereof.

Afterward, a first interlayer dielectric layer 134B is formed over the contact etching stop layer 132B, as shown in FIGS. 3C-1 and 3C-2, in accordance with some embodiments. The first interlayer dielectric layer 134B overfills the space between dummy gate structures 112, in accordance with some embodiments. In some embodiments, the first interlayer dielectric layer 134B is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material.

In some embodiments, the first interlayer dielectric layer 134B and the contact etching stop layer 132B are made of different materials and have a great difference in etching selectivity. In some embodiments, the dielectric material for the first interlayer dielectric layer 134B is deposited using such as CVD (such as HDP-CVD, PECVD, HARP or FCVD), another suitable technique, or a combination thereof. The dielectric materials for the contact etching stop layer 132B and the first interlayer dielectric layer 134B above the top surface of the dummy gate electrode layer 116 are removed using such as CMP, and then are etched-back until the side surfaces of the second semiconductor layer 108T are exposed, in accordance with some embodiments.

Top source/drain features 122T are grown from the exposed side surfaces of the second semiconductor layers 108T in the source/drain recesses 120 using an epitaxial growth process, as shown in FIGS. 3C-1 and 3C-2, in accordance with some embodiments. The epitaxial growth process may be MBE, MOCVD, or VPE, or another suitable technique.

In some embodiments, the top source/drain features 122T are made of any suitable semiconductor material for n-type semiconductor devices or p-type semiconductor devices. In some embodiments, the top source/drain features 122T are doped. The concentration of the dopant in the top source/drain features 122T in a range from about 1×10¹⁹ cm⁻³ to about 6×10²¹ cm⁻³. In some embodiments where the top device region of the active region 104 is to be formed as n-type devices (e.g., n-channel nanostructure transistors), the top source/drain features 122T are made of semiconductor material such as SiP, SiAs, SiCP, SiC, Si, GaAs, another suitable semiconductor material, or a combination thereof. In some embodiments, the top source/drain features 122T are doped with the n-type dopant during the epitaxial growth process. For example, the n-type dopant may be phosphorous (P) or arsenic (As). For example, the top source/drain features 122T may be the epitaxially grown Si doped with phosphorous to form silicon:phosphor (Si:P) source/drain features and/or arsenic to form silicon:arsenic (Si:As) source/drain feature.

In some other embodiments where the bottom device region is used to form n-type devices and the top device region is used to form p-type devices, the bottom source/drain features 122B are doped with n-type dopants while the top source/drain features 122T are doped with p-type dopants.

A contact etching stop layer 132T is formed over the semiconductor structure 100A to cover the top source/drain features 122T, and a first interlayer dielectric layer 134T is formed over the contact etching stop layer 132T, in accordance with some embodiments. In some embodiments, the material of the contact etching stop layer 132T and the first interlayer dielectric layer 134T may be the same as or similar to the material of the contact etching stop layer 132B and the first interlayer dielectric layer 134B, respectively.

The dielectric materials for the contact etching stop layer 132T and the first interlayer dielectric layer 134T above the top surface of the dummy gate electrode layer 116 are removed using such as CMP to expose the top surfaces of the dummy gate structures 112, in accordance with some embodiments. The patterned hard mask layer 117 is removed, in accordance with some embodiments

FIGS. 3D-1 and 3D-2 illustrate the semiconductor structure 100A after the formation of gate trenches 136 and gaps 138, in accordance with some embodiments.

The dummy gate structures 112 are removed using an etching process to form gate trenches 136 between the gate spacer layers 118, as shown in FIGS. 3D-1 and 3D-2, in accordance with some embodiments. In some embodiments, the gate trenches 136 expose the channel regions of the active region 104. In some embodiments, the gate trenches 136 further expose the sidewalls of the gate spacer layers 118 facing the channel regions. In some embodiments, the etching process includes plasma dry etching, a dry chemical etching, and/or a wet etching.

Afterward, an etching process is performed on the first semiconductor layers 106B and 106T to form gaps 138, as shown in FIGS. 3D-1 and 3D-2, in accordance with some embodiments. In some embodiments, the gaps 138 expose the sidewalls of the inner spacer layers 124 facing the channel region. The inner spacer layers 124 may be used as an etching stop layer in the etching process, which may protect the source/drain features 122B and 122T from being damaged. In some embodiments, the etching process includes plasma dry etching, a dry chemical etching, and/or a wet etching.

After the etching processes, the main surfaces of the second semiconductor layers 108B and 108T are exposed, in accordance with some embodiments. The exposed second semiconductor layers 108B and 108T form nanostructures 108B and 108T, in accordance with some embodiments. The nanostructures 108B and 108T are vertically stacked and spaced apart from one other, in accordance with some embodiments. The nanostructure 108B functions as the channel of the bottom device of the CFET, and the nanostructure 108T functions as the channel of the top device of the CFET, in accordance with some embodiments. Although one nanostructure 108B and one nanostructure are shown in FIGS. 3D-1, the number is not limited to one, and can be two (as shown in FIG. 1) or three, and is less than 10.

FIGS. 3E-1 and 3E-2 illustrate the semiconductor structure 100A after the formation of final gate stacks 140, in accordance with some embodiments.

Final gate stacks 140 are formed in the gate trenches 136 and gaps 138, as shown in FIGS. 3E-1 and 3E-2, in accordance with some embodiments. The nanostructures 108B and 108T are wrapped by the final gate stacks 140, in accordance with some embodiments. In some embodiments, the final gate stacks 140 extend in the Y direction. The final gate stacks 140 have longitudinal axes parallel to the Y direction, in accordance with some embodiments. In some embodiments, each of the final gate stacks 140 includes an interfacial layer 142, a gate dielectric layer 144 and a metal gate electrode layer 146, as shown in FIGS. 3E-1 and 3E-2, in accordance with some embodiments.

The interfacial layer 142 is formed on the exposed surfaces of the nanostructures 108B and 108T, in accordance with some embodiments. The interfacial layer 142 wraps around the nanostructures 108B and 108T, in accordance with some embodiments. In some embodiments, the interfacial layer 142 is made of a chemically formed silicon oxide. In some embodiments, the interfacial layer 142 is nitrogen-doped silicon oxide. In some embodiments, the interfacial layer 142 is formed using one or more cleaning processes such as including ozone (O₃), ammonia hydroxide-hydrogen peroxide-water mixture, and/or hydrochloric acid-hydrogen peroxide-water mixture. Semiconductor material from the nanostructures 108B and 108T and the lower fin element 104L is oxidized to form the interfacial layer 142, in accordance with some embodiments.

The gate dielectric layer 144 is formed conformally along the interfacial layer 142 to be wrapped around the nanostructures 108B and 108T, in accordance with some embodiments. The gate dielectric layer 144 is also conformally formed along the sidewalls of the gate spacer layers 118 facing the channel regions, in accordance with some embodiments. The gate dielectric layer 144 is also conformally formed along the sidewalls of the inner spacer layers 124 facing the channel regions, in accordance with some embodiments.

The gate dielectric layer 144 may be high-k dielectric layer. In some embodiments, the high-k dielectric layer is dielectric material with high dielectric constant (k value), for example, greater than 9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Si₃N₄, oxynitride (SiON), a combination thereof, or another suitable material. The high-k dielectric layer may be deposited using ALD, PVD, CVD, and/or another suitable technique.

The metal gate electrode layer 146 is formed to overfill remainders of the gate trenches 136 and gaps 138, in accordance with some embodiments. In some embodiments, the metal gate electrode layer 146 is made of more than one conductive material, such as a metal, metal alloy, conductive metal oxide and/or metal nitride, another suitable conductive material, and/or a combination thereof. For example, the metal gate electrode layer 146 may be made of Ti, Ag, Al, TiAlN, TaC, TaCN, TaSiN, Mn, Zr, TiN, TaN, Ru, Mo, WN, Cu, W, Re, Ir, Co, Ni, another suitable conductive material, or multilayers thereof.

The metal gate electrode layer 146 may be a multi-layer structure with various combinations of a diffusion barrier layer, work function layers with a selected work function to enhance the device performance (e.g., threshold voltage) for n-channel FETs or p-channel FETs, a capping layer to prevent oxidation of work function layers, a glue layer to adhere work function layers to the next layer, and a metal fill layer to reduce the total resistance of gate stacks, and/or another suitable layer. The metal gate electrode layer 146 may be formed using ALD, PVD, CVD, e-beam evaporation, or another suitable technique.

In some embodiments, the metal gate electrode layer 146 may be or includes a single work function metal that continuously surrounds the nanostructures 108B and 108T. In some other embodiments where the bottom device region is used to form p-type devices and the top device region is used to form n-type devices, the metal gate electrode layer 146 includes a p-type work function metal surrounding the nanostructure 108B, and an n-type work function metal surrounding the nanostructure 108T.

A planarization process such as CMP may be performed on the semiconductor structure 100A to remove the materials of the gate dielectric layer 144 and the metal gate electrode layer 146 formed above the top surface of the first interlayer dielectric layer 134T, in accordance with some embodiments.

The bottom portion of the final gate stacks 140 that are wrapped around the bottom nanostructure 108B combine with the neighboring bottom source/drain features 122B to form a bottom transistor BT, e.g., a p-channel nanostructure transistor. The top portion of the final gate stacks 140 that is wrapped around the top nanostructure 108T combine with the neighboring top source/drain features 122T to form a top transistor TT, e.g., an n-channel nanostructure transistor.

The n-channel top transistor TT is directly stacked above the p-channel bottom transistors BT thereby constructing a CFET, in accordance with some embodiments. The final gate stacks 140 engage the channel region of the CFET so that current can flow between the source/drain features 122B/122T during operation. In some other embodiments, the top transistors TT are p-channel nanostructure transistors, and the bottom transistors BT are n-channel nanostructure transistors.

FIGS. 3F-1, 3F-2 and 3F-3 illustrate the semiconductor structure 100A after the formation of an etching stop layer 148, a second interlayer dielectric layer 150, and frontside contact structures 152A and 152B, in accordance with some embodiments.

The bottom source/drain feature used for a Vdd/Vss node (e.g., source terminal) is denoted as 122B1, and the top source/drain feature used for a Vdd/Vss node (e.g., source terminal) is denoted as 122T1, as shown in FIGS. 3F-1 and 3F-2, in accordance with some embodiments. The top source/drain feature 122T1 vertically overlaps the bottom source/drain feature 122B1, in accordance with some embodiments.

The bottom source/drain feature used for a non-Vdd/Vss node (e.g., drain terminal) is denoted as 122B2, and the top source/drain feature used for a non-Vdd/Vss node (e.g., drain terminal) is denoted as 122T2, as shown in FIGS. 3F-1 and 3F-3, in accordance with some embodiments. The top source/drain feature 122T2 vertically overlaps the bottom source/drain feature 122B2, in accordance with some embodiments.

An etching stop layer 148 and a second interlayer dielectric layer 150 are sequentially formed over the semiconductor structure 100A, as shown in FIGS. 3F-1, 3F-2 and 3F-3, in accordance with some embodiments. In some embodiments, the etching stop layer 148 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, the second interlayer dielectric layer 150 is made of dielectric material, such as USG, BPSG, FSG, PSG, BSG, and/or another suitable dielectric material. In some embodiments, the etching stop layer 148 and the second interlayer dielectric layer 150 are deposited using CVD (such as HDP-CVD, PECVD, HARP or FCVD), another suitable technique, or a combination thereof.

Contact structures 152A and 152B are formed, as shown in FIGS. 3F-1, 3F-2 and 3F-3, in accordance with some embodiments. The contact structure 152A penetrates through the second interlayer dielectric layer 150, the etching stop layer 148, the first interlayer dielectric layer 134T and the contact etching stop layer 132T, and lands on and is electrically connected to the top source/drain feature 122T1, in accordance with some embodiments. In some embodiments, the contact structure 152A is wider than the source/drain features 122T1 and 122B1 in the Y direction, and the contact structure 152B is wider than the source/drain features 122T2 and 122B2 in the Y direction. In some embodiments, the contact structure 152A exceeds the sidewalls of the source/drain features 122B1 and 122T1 in the Y direction. In some embodiments, the contact structure 152B exceeds the sidewalls of the source/drain features 122B2 and 122T2 in the Y direction.

In some embodiments, the interface between the contact structure 152A and the top source/drain feature 122T1 is flat. In some embodiments, the interface between the contact structure 152B and the top source/drain feature 122T2 is flat. In some embodiments, the interface between the contact structure 152B and the bottom source/drain feature 122B2 is flat. In some other embodiments, the interface between the contact structure 152A and the top source/drain feature 122T1 is curved. In some other embodiments, the interface between the contact structure 152B and the top source/drain feature 122T2 is curved. In some other embodiments, the interface between the contact structure 152B and the bottom source/drain feature 122B2 is curved.

The contact structure 152B penetrates through the second interlayer dielectric layer 150, the etching stop layer 148, the first interlayer dielectric layer 134T and the contact etching stop layer 132T to land on the top source/drain features 122T2, and includes a portion which further penetrates through the top source/drain features 122T2, the first interlayer dielectric layer 134B and the contact etching stop layer 132B to land on the bottom source/drain feature 122B2, in accordance with some embodiments. The contact structure 152B is electrically connected to the top source/drain features 122T2 and the bottom source/drain feature 122B2, in accordance with some embodiments. The contact structures 152A and 152B may be also referred to as frontside contact structures.

In some embodiments, the formation of the contact structures 152A and 152B includes patterning the semiconductor structure 100A to form contact openings (where the contact structures 152A and 152B are to be formed) using one or more photolithography and etching processes to expose the source/drain features 122T1, 122T2 and 122B2.

Contact liners 155 are formed along the sidewalls of the contact openings using a deposition process and an etching back process, in accordance with some embodiments. In some embodiments, the contact liners 155 can be an insulating material or a dielectric material (e.g., LaO, AlO, AlON, ZrO, HfO, SiN, ZnO, ZrN, ZrAlO, TiO, TaO, YO, TaCN, ZrSi, SiOCN, SiOC, SiCN, SiN, HfSi, or SiO); or undoped silicon (Si).

Silicide layers 154 are formed on the exposed surfaces of the source/drain features 122T1, 122T2 and 122B2. In some embodiments, the silicide layers 154 are made of WSi, NiSi, TiSi and/or CoSi.

Afterward, one or more conductive materials for the contact structures 152A and 152B are deposited to overfill the contact openings, in accordance with some embodiments. In some embodiments, one or more conductive materials are deposited using CVD, PVD, e-beam evaporation, ALD, electroplating (ECP), electroless deposition (ELD), another suitable method, or a combination thereof to overfill the contact openings. The one or more conductive materials over the upper surface of the second interlayer dielectric layer 150 are planarized using, for example, CMP.

The contact structures 152A and 152B may have a multilayer structure. For example, a barrier/adhesive layer (not shown) may optionally be deposited along the sidewalls and the bottom surfaces of the contact openings. The barrier/adhesive layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the contact openings. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

FIGS. 3G-1, 3G-2 and 3G-3 illustrate the semiconductor structure 100A after the formation of a frontside interconnect structure 156, a bonding dielectric material 158, and a carrier substrate 160, in accordance with some embodiments.

A frontside interconnect structure 156 is formed over the semiconductor structure 100A, as shown in FIGS. 3G-1, 3G-2 and 3G-3, in accordance with some embodiments. In some embodiments, the frontside interconnect structure 156 includes a combination of vertically-stacked multiple levels of dielectric layers and electrically conductive features formed therein. The dielectric layers may include silicon oxide (SiO), silicon nitride (SiN), silicon oxynitride (SiON), dielectric material(s) with low dielectric constant (low-k) such as SiCOH, SiOCN, SiOC, USG, BPSG, FSG, PSG, BSG, and/or an extreme low-k (ELK) dielectric material with a dielectric constant (k) less than about 3.0.

The conductive features are configured to form vertical interconnect features (providing, for example, vertical connection between features and/or vertical electrical routing), such as vias, and/or horizontal interconnect features (providing, for example, horizontal electrical routing), such as metal lines, in accordance with some embodiments. Vertical conductive features of an interconnect structure typically connect horizontal conductive features in different layers (or different planes) of the multilayer interconnect structure, in accordance with some embodiments. The conductive features may be made of Ta, TaN, Ti, TiN, CoW, Co, Ni, W, Ti, Ta, Cu, Rh, Ir, Pt, Al, Ru, Mo, or a combination thereof.

In some embodiments where the bottom transistor BT is a p-channel FET, and the top transistor TT is an n-channel FET, the top source/drain features 122T1 of the top transistor TT is electrically connected to a Vss frontside power rail formed in a frontside first-level metal layer (M1). In some embodiments, the source/drain features 122T2 and 122B are electrically connected to a signal line in the frontside first-level metal layer (M1). In some embodiments, the final gate stack 140 is electrically connected to a signal line in the frontside first-level metal layer (M1).

A bonding dielectric material 158 is formed over the semiconductor structure 100A, as shown in FIGS. 3G-1, 3G-2 and 3G-3, in accordance with some embodiments. In some embodiments, the bonding dielectric material 158 is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), AlN, BN, SiC, BeO, or a combination thereof. In some embodiments, the bonding dielectric material 158 is deposited using CVD (such as LPCVD, PECVD, or HDP-CVD), ALD, another suitable technique, or a combination thereof.

A carrier substrate 160 is bonded to the frontside surface of the semiconductor structure 100A, as shown in FIGS. 3G-1, 3G-2 and 3G-3, in accordance with some embodiments. In some embodiments, the carrier substrate 160 is a semiconductor substrate, a ceramic substrate, a glass substrate, a polymer substrate, or another suitable substrate.

FIGS. 3H-1, 3H-2 and 3H-3 illustrate the semiconductor structure 100A after flipping the semiconductor structure 100A and a planarization process, in accordance with some embodiments.

The semiconductor structure 100A (or the semiconductor substrate 102) is flipped upside down, as shown in FIGS. 3H-1, 3H-2 and 3H-3, in accordance with some embodiments. After flipping the semiconductor structure 100A, the backside surface of the substrate 102 (or the backside of the semiconductor structure 100A) faces upward, in accordance with some embodiments.

The substrate 102 is removed from the backside of the semiconductor structure 100A using such as CMP, a grinding process, an etching process, or a combination thereof until the isolation structure 110 are exposed, as shown in FIGS. 3H-1, 3H-2 and 3H-3, in accordance with some embodiments. In some embodiments, the lower fin element 104L is further thinned down in the planarization process.

FIGS. 3I-1, 3I-2 and 3I-3 illustrate the semiconductor structure 100A after the formation of a contact opening 166, in accordance with some embodiments.

A patterned mask layer 162 is formed over the backside of the semiconductor structure 100A, as shown in FIGS. 3I-1, 3I-2 and 3I-3, in accordance with some embodiments. The patterned mask layer 162 has an opening pattern 164 corresponding (or being substantially aligned with) the bottom source/drain features 122B1, in accordance with some embodiments. The patterned mask layer 162 covers the bottom source/drain features 122B2, in accordance with some embodiments.

The patterned mask layer 162 may be a patterned mask layer and/or a patterned photoresist layer. For example, a hard mask layer may be globally deposited using ALD or CVD over the semiconductor structure 100A. The hard mask layer is made of silicon-containing dielectric material such as silicon nitride (SiN), silicon oxynitride (SiON), silicon oxide (SiO₂), silicon oxynitride (SiOC), silicon carbide (SiC), or oxygen-doped silicon carbonitride (Si(O)CN); a metal oxide dielectric such as Al₂O₃, LaO, HfO₂, Ta₂O₅, TiO₂, ZrO₂, or Y₂O₃; another suitable mask material; or a combination thereof. A patterned photoresist layer is formed on the hard mask layer using a photolithography process. The photolithography process may include forming a photoresist material, performing a pre-exposure baking process, performing an exposure process using a mask (or a reticle), performing a post-exposure baking process, and performing a developing process.

Afterward, the hard mask layer is etched using the patterned photoresist layer, in accordance with some embodiments. In some embodiments, the etching process may be an anisotropic etching process such as dry plasma etching, an isotropic etching process such as dry chemical etching, remote plasma etching, wet chemical etching, or a combination thereof. The patterned photoresist may be removed in the etching process or by an additional process (e.g., etching or ashing process).

An etching process is performed using the patterned mask layer 162 to remove the portion of the lower fin element 104L of the active region 104 exposed from the opening pattern 164, thereby forming a contact opening 166, as shown in FIGS. 3I-1, 3I-2 and 3I-3, in accordance with some embodiments. The etching process may include dry etching such as RIE, NBE, ICP etch, CCP etch, another suitable method, or a combination thereof. Afterward, the patterned mask layer 162 is removed using an etching process.

The contact opening 166 exposes the backside surface (i.e., the top surfaces in the current schematics) of the bottom source/drain feature 122B1, in accordance with some embodiments. In some embodiments, the backside surface of the bottom source/drain feature 122B2 used for the drain terminal remains covered by and in direct contact with the lower fin element 104L. That is, no contact structure will be formed on the backside surface of the bottom source/drain feature 122B2.

FIGS. 3J-1, 3J-2 and 3J-3 illustrate the semiconductor structure 100A after the formation of a contact liner 167, in accordance with some embodiments.

A contact liner 167 is formed along the sidewalls of the contact opening 166 using a deposition process and an etching back process, in accordance with some embodiments. In some embodiments, the contact liner 167 is made of an insulating material such as a dielectric material (e.g., SiC, LaO, AlO, AlON, ZrO, HfO, SiN, ZnO, ZrN, ZrAlO, TiO, TaO, YO, TaCN, ZrSi, SiOCN, SiOC, SiCN, SiN, HfSi, or SiO); or undoped silicon (Si).

FIGS. 3K-1, 3K-2 and 3K-3 illustrate the semiconductor structure 100A after the formation of a backside contact structure 168 and a backside interconnect structure 172, in accordance with some embodiments. The cross-sectional views illustrate the semiconductor structure 100A after flipping upside down, and thus the frontside of the semiconductor structure 100A shown in FIGS. 3K-1, 3K-2 and 3K-3 faces upward, in accordance with some embodiments.

A silicide layers 170 is formed on the exposed surfaces of the backside surface of the bottom source/drain feature 122B1, as shown in FIGS. 3K-1, 3K-2 and 3K-3, in accordance with some embodiments. In some embodiments, the silicide layers 170 are made of WSi, NiSi, TiSi and/or CoSi.

The formation of the contact structure 168 includes depositing one or more conductive materials to overfill the contact opening 166, in accordance with some embodiments. In some embodiments, one or more conductive materials are deposited using CVD, PVD, e-beam evaporation, ALD, electroplating (ECP), electroless deposition (ELD), another suitable method, or a combination thereof to overfill the contact openings. The one or more conductive materials over the upper surface of the second interlayer dielectric layer 150 are planarized using, for example, CMP.

The contact structure 168 may have a multilayer structure, e.g., including a barrier/adhesive layer and a metal bulk layer on the barrier/adhesive layer. The barrier/adhesive layer may be made of tantalum (Ta), tantalum nitride (TaN), titanium (Ti), titanium nitride (TiN), cobalt tungsten (CoW), another suitable material, or a combination thereof. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

In some embodiments, the backside contact structure 168 is formed in a self-aligned manner in the location of the lower fin element 104, and thus the backside contact structure 168 is confined within the area of the source/drain features 122B1 and 122T1 in the top view. That is, the backside contact structure 168 does not exceed the sidewalls of the source/drain features 122B1 and 122T1 in the Y direction. In some embodiments, the contact structure 168 is narrow than the source/drain features 122B1 and 122T1 in the Y direction. In some embodiments, the contact structure 168 is narrow than the contact structure 152A in the Y direction.

FIG. 3L illustrates a modification of the semiconductor structure 100A of FIG. 3K-2. In some embodiments, the contact structure 168 can have a shape that tapers toward the source/drain feature 122B1. In some embodiments, the bottom portion of the contact structure 168 away from the source/drain feature 122B1 is wider than the upper portion of the contact structure 168 close to the source/drain feature 122B1.

A backside interconnect structure 172 is formed over the backside of the semiconductor structure 100A, as shown in FIGS. 3K-1, 3K-2 and 3K-3, in accordance with some embodiments. In some embodiments, the backside interconnect structure 172 includes a combination of vertically-stacked multiple levels of dielectric layers and electrically conductive features formed therein. The materials of dielectric layers and the conductive features may be similar to the of dielectric layers and the conductive features described above.

In some embodiments where the bottom transistor BT is a p-channel FET, and the top transistor TT is an n-channel FET, the bottom source/drain feature 122B1 of the bottom transistor BT is electrically connected to a Vdd backside power rail formed in a backside first-level metal layer (BM1) through the backside contact structure 168. In some embodiments, the metal layers in frontside interconnect structure 156 may be electrically connected to the metal layers in the backside interconnect structure 172 though a transmission feature (e.g., a feedthrough via) formed in another cell region of the substrate 102.

In accordance with the embodiments of the present disclosure, a non-metallic structure (e.g., the silicon-containing lower fin element 104L) is formed on the backside surface of the bottom source/drain feature 122B2 for the non-Vdd/Vss node of the bottom device, rather than a metallic structure being formed on the backside surface of the bottom source/drain feature 122B2. Because no backside contact structure is formed on the backside surface of the bottom source/drain feature 122B2, the parasitic capacitance of the bottom device BT may be reduced, and thus the overall cell capacitance of the CFET device may be reduced. Therefore, the performance of the resulting semiconductor device may be enhanced, e.g., with faster speed and lower power consumption.

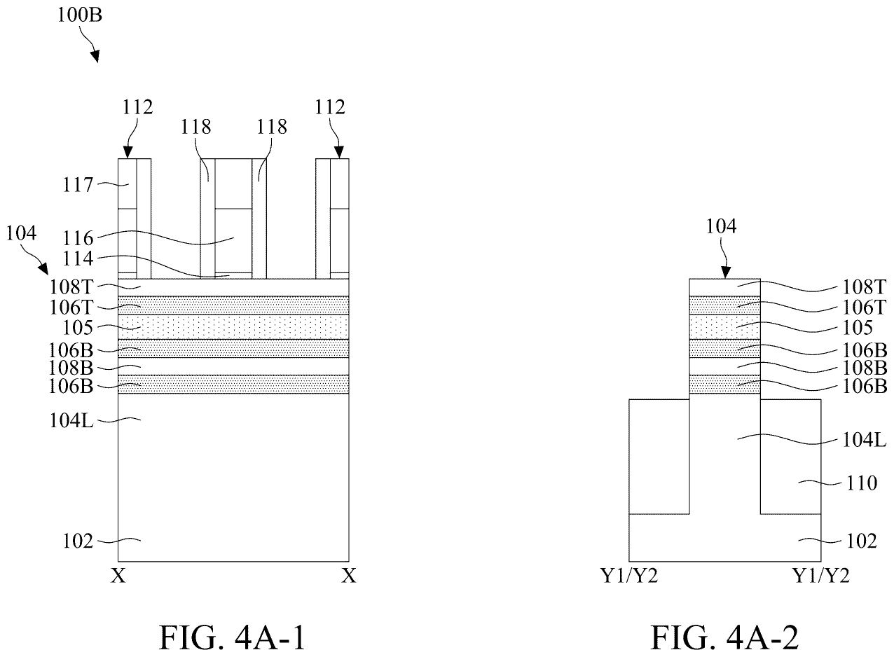

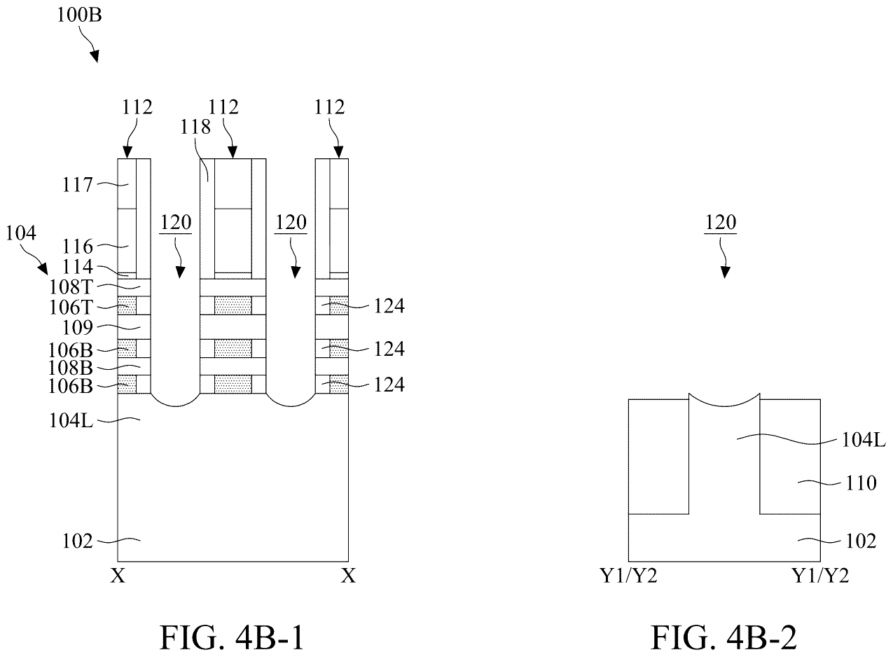

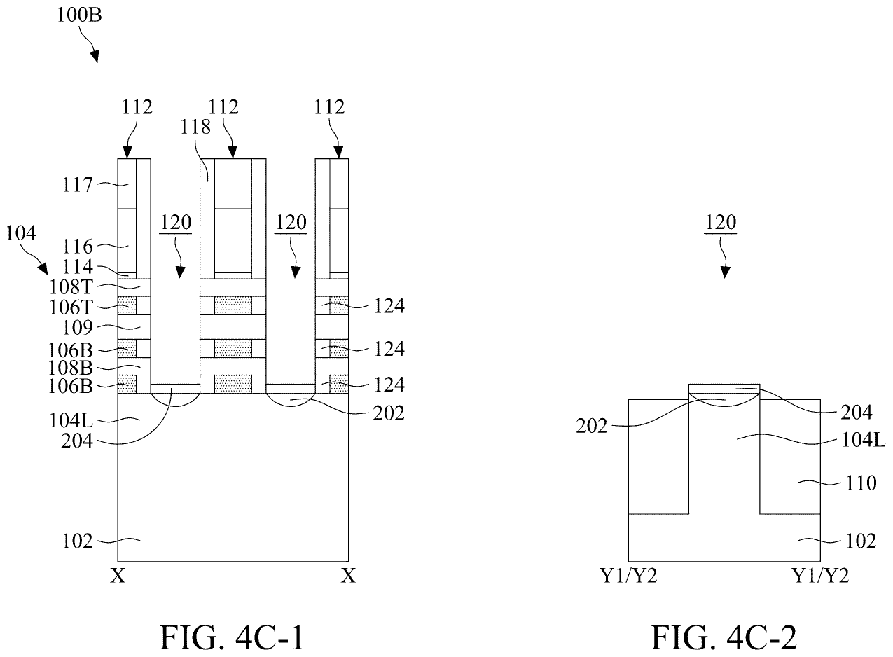

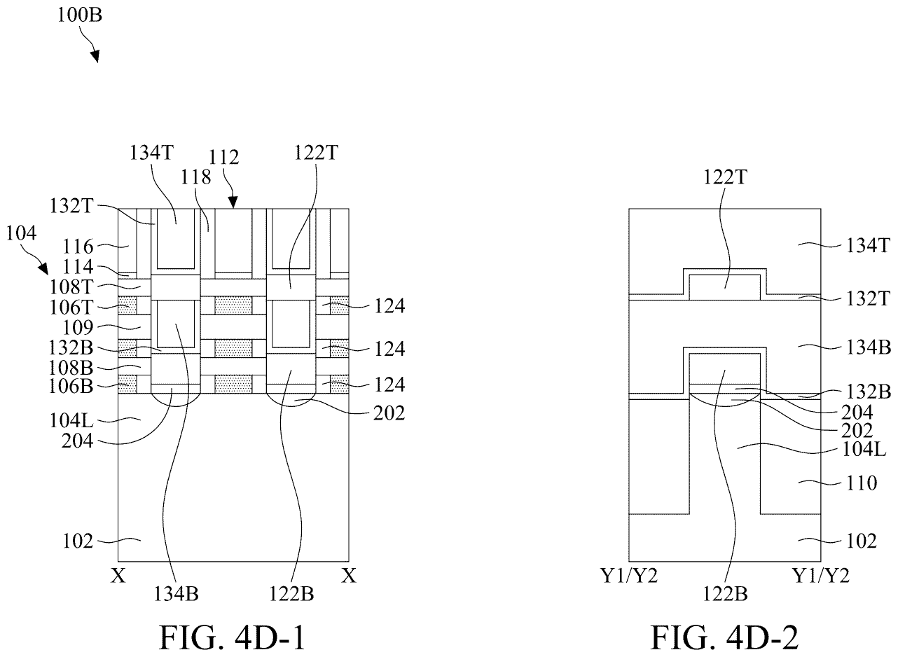

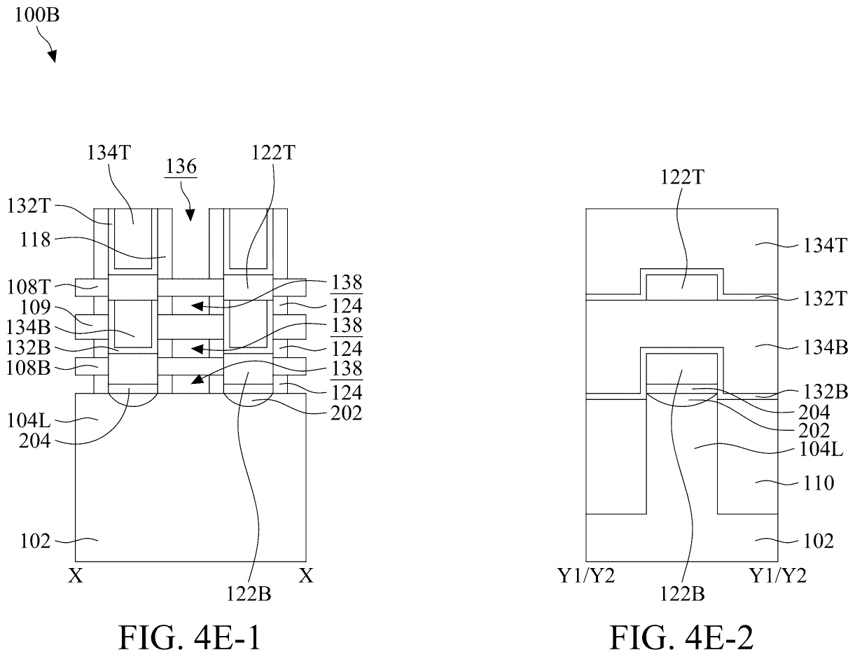

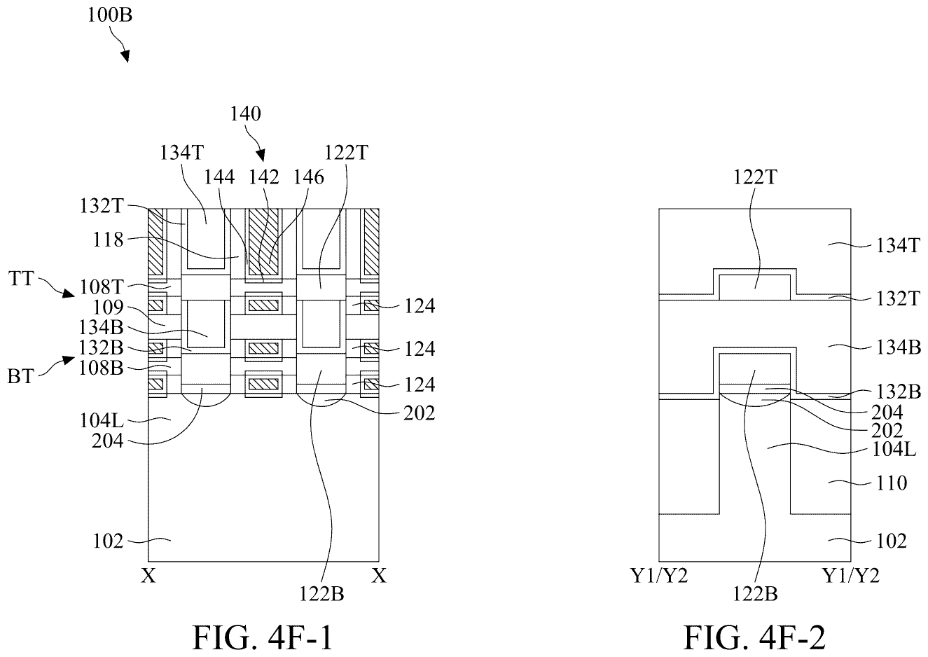

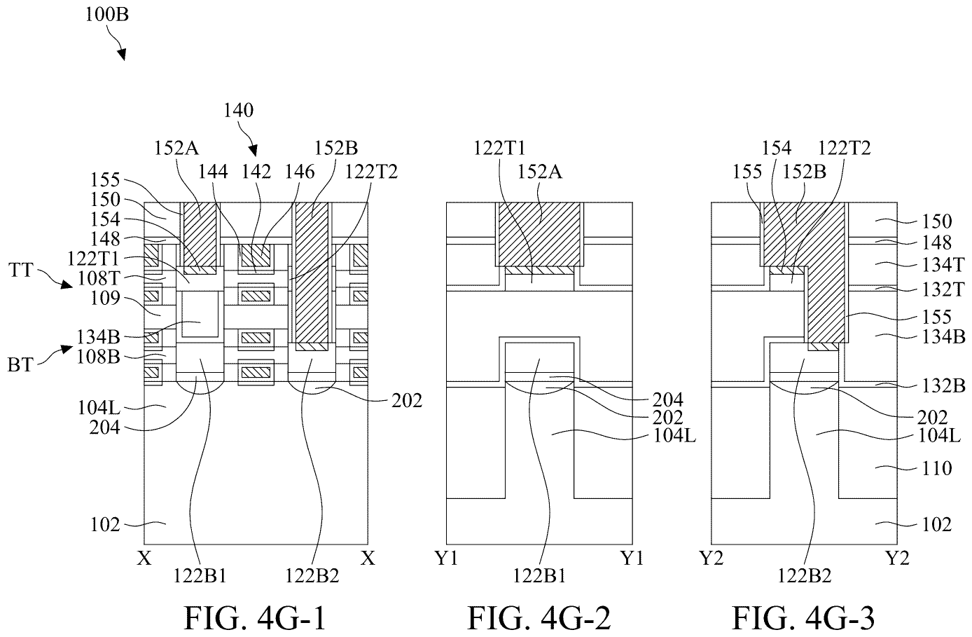

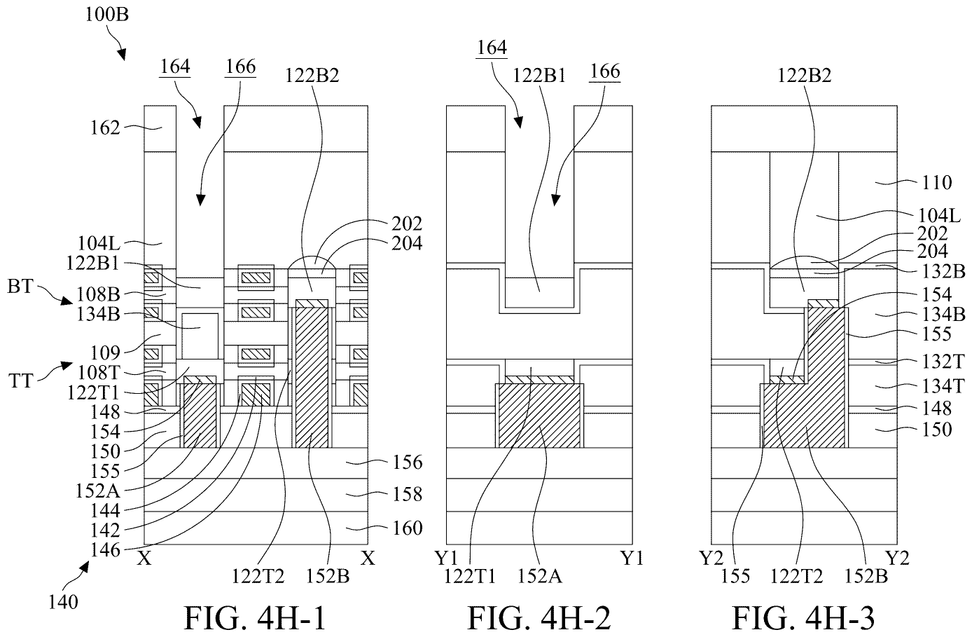

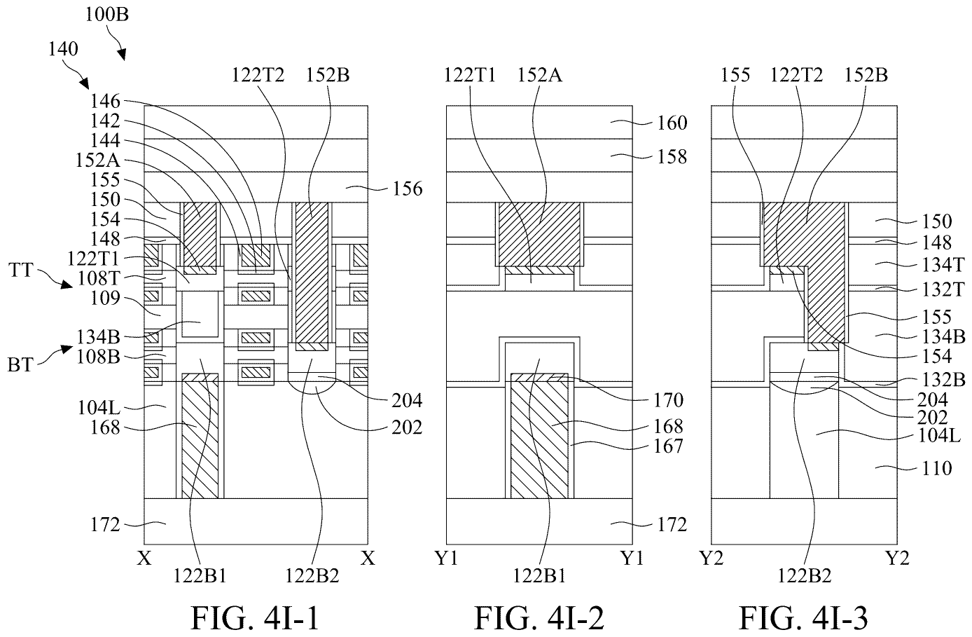

FIGS. 4A-1 through 4I-3 are cross-sectional views illustrating the formation of the semiconductor structure of FIG. 2 at various intermediate stages, in accordance with some embodiments of the disclosure. FIGS. 4A-1, 4B-1, 4C-1, 4D-1, 4E-1, 4F-1, 4G-1, 4H-1 and 4I-1 correspond to line X-X of FIG. 2. FIGS. 4A-2, 4B-2, 4C-2, 4D-2, 4E-2 and 4F-2 correspond to line Y1-Y1 or line Y2-Y2 of FIG. 2. FIGS. 4G-2, 4H-2 and 4I-2 correspond to line Y1-Y1 of FIG. 2. FIGS. 4G-3, 4H-3 and 4I-3 correspond to line Y2-Y2 of FIG. 2. The embodiments of FIGS. 4A-1 to 4I-3 are similar to the embodiments of FIGS. 3A-1 to 3K-3 except that a separation layer, such as a dielectric isolation feature 204 is formed between the bottom source/drain feature 122B2 and the lower fin element 104L.

A semiconductor structure 100B is provided, as shown in FIGS. 4A-1 and 4A-2, in accordance with some embodiments. The semiconductor structure 100B includes an active region 104 over the substrate 102, and an isolation structure 110 surrounding the lower fin element 104L of the active region 104, in accordance with some embodiments. Dummy gate structures 112 are formed across the active region 104 and the isolation structure 110, and gate spacer layers 118 are formed along opposite sidewalls of the dummy gate structures 112, in accordance with some embodiments.

An etching process is performed to recess the source/drain regions of the active region 104, thereby forming source/drain recesses 120, as shown in FIGS. 4B-1 and 4B-3, in accordance with some embodiments. An etching process is performed to remove the middle layer 105, thereby forming a gap, and then an insulating layer 109 is formed in the gap, in accordance with some embodiments. An etching process is then performed to laterally recess, from the source/drain recesses 120, the first semiconductor layers 106B and 106T of the active region 104, thereby forming notches, and then inner spacer layers 124 are formed in the notches, in accordance with some embodiments.

FIGS. 4C-1 and 4C-2 illustrate the semiconductor structure 100B after the formation of separation layer 202 and dielectric isolation features 204, in accordance with some embodiments.

Semiconductor isolation features 202 are formed in the source/drain recesses 120 on the lower fin element 104L, as shown in FIGS. 4C-1 and 4C-2, in accordance with some embodiments. In some embodiments, the separation layers 202 are made of an epitaxial semiconductor material such as non-doped silicon, formed by MBE, MOCVD, or VPE, another suitable technique, or a combination thereof.

Dielectric isolation features 204 are formed on the separation layers 202 in the source/drain recesses 120, as shown in FIGS. 4C-1 and 4C-2, in accordance with some embodiments. In some embodiments, the separation layers 202 abut the bottommost inner spacer layers 124. In some embodiments, the top surfaces of the dielectric isolation features 204 are lower than the bottom surface of the second semiconductor layers 108B.

In some embodiments, the dielectric isolation features 204 are made of a dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN), or high-k dielectric material (e.g., with dielectric constant greater than about 7.9) such as LaO, AlO, AlON, ZrO, HfO, ZnO, ZrN, ZrAlO, TiO, TaO, YO, TaCN, or a combination thereof. In some embodiments, the dielectric isolation features 126 are deposited using a technique such as ALD, CVD (such as HDP-CVD, LPCVD or PECVD), another suitable technique, or a combination thereof, followed by an etching-back process.

Bottom source/drain features 122B are grown from the exposed side surfaces of the second semiconductor layers 108B in the source/drain recesses 120, as shown in FIGS. 4D-1 and 4D-2, in accordance with some embodiments. A contact etching stop layer 132B is formed to cover the bottom source/drain features 122B, and a first interlayer dielectric layer 134B is formed over the contact etching stop layer 132B, in accordance with some embodiments.

Top source/drain features 122T are grown from the exposed side surfaces of the second semiconductor layers 108T, as shown in FIGS. 4D-1 and 4D-2, in accordance with some embodiments. A contact etching stop layer 132T is formed to cover the top source/drain features 122T, and a first interlayer dielectric layer 134T is formed over the contact etching stop layer 132T, in accordance with some embodiments.

The dummy gate structures 112 are removed using an etching process to form gate trenches 136, and an etching process is performed on the first semiconductor layers 106B and 106T to form gaps 138, as shown in FIGS. 4E-1 and 4E-2, in accordance with some embodiments. The exposed second semiconductor layers 108B and 108T form nanostructures 108B and 108T, in accordance with some embodiments.

Final gate stacks 140 are formed in the gate trenches 136 and gaps 138, as shown in FIGS. 4E-1 and 4E-2, in accordance with some embodiments. The nanostructures 108B and 108T are wrapped by the final gate stacks 140, in accordance with some embodiments.

The bottom portion of the final gate stacks 140 that are wrapped around the bottom nanostructure 108B combine with the neighboring bottom source/drain features 122B to form a bottom transistor BT. The top portion of the final gate stacks 140 that are wrapped around the top nanostructure 108T combine with the neighboring top source/drain features 122T to form a top transistor TT. The n-channel top transistor TT is directly stacked above the p-channel bottom transistors BT thereby constructing a CFET, in accordance with some embodiments.

An etching stop layer 148 and a second interlayer dielectric layer 150 are sequentially formed over the semiconductor structure 100B, as shown in FIGS. 4G-1, 4G-2 and 4G-3, in accordance with some embodiments. A contact structure 152A is formed to land on the top source/drain feature 122T1, and a contact structure 152B is formed to land on the top source/drain features 122T2 and the bottom source/drain feature 122B2, in accordance with some embodiments.

A frontside interconnect structure 156 is formed over the semiconductor structure 100B, a bonding dielectric material 158 is formed over the frontside interconnect structure 156, and a carrier substrate 160 is bonded to the frontside surface of the semiconductor structure 100B, as shown in FIGS. 4H-1, 4H-2 and 4H-3, in accordance with some embodiments. The semiconductor structure 100B (or the semiconductor substrate 102) is flipped upside down, and the substrate 102 is removed from the backside of the semiconductor structure 100B, in accordance with some embodiments.

A patterned mask layer 162 is formed over the backside of the semiconductor structure 100B, as shown in FIGS. 4H-1, 4H-2 and 4H-3, in accordance with some embodiments. An etching process is performed using the patterned mask layer 162 to remove the portion of the lower fin element 104L of the active region 104, the separation layer 202 and the dielectric isolation feature 204 which are corresponding to the opening pattern 164, thereby forming a contact opening 166, as shown in FIGS. 4H-1, 4H-2 and 4H-3, in accordance with some embodiments.

The contact opening 166 exposes the backside surface (i.e., the top surfaces in the current schematics) of the bottom source/drain feature 122B1, in accordance with some embodiments. In some embodiments, the backside surface of the bottom source/drain feature 122B2 used for the drain terminal remains covered by and in direct contact with the dielectric isolation feature 204. That is, no contact structure will be formed on the backside surface of the bottom source/drain feature 122B2.

A contact liner 167 is formed along the sidewalls of the contact opening 166, a silicide layer 170 is formed on the backside surface of the bottom source/drain feature 122B1, and a contact structure 168 is formed in the contact opening 166 to land on the backside surface of the bottom source/drain feature 122B1, as shown in FIGS. 4I-1 and 4I-2, in accordance with some embodiments. A backside interconnect structure 172 is formed over the backside of the semiconductor structure 100B, in accordance with some embodiments. In some embodiments where the bottom transistor BT is a p-channel FET, and the top transistor TT is an n-channel FET, the top source/drain features 122T1 of the top transistor TT is electrically connected to a Vss frontside power rail formed in a frontside first-level metal layer (M1), and the bottom source/drain feature 122B1 of the bottom transistor BT is electrically connected to a Vdd backside power rail formed in a backside first-level metal layer (BM1) through the backside contact structure 168.

In accordance with the embodiments of the present disclosure, a non-metallic structure (e.g., the dielectric isolation feature 204) is formed on the backside surface of the bottom source/drain feature 122B2 for the non-Vdd/Vss node of the bottom device, rather than a metallic structure being formed on the backside surface of the bottom source/drain feature 122B2. Because the dielectric isolation feature 204 is formed between the bottom source/drain feature 122B2 and the lower fin element 104L, the parasitic capacitance of the bottom device BT may be further reduced, and thus the overall cell capacitance of the CFET device may be further reduced. In addition, the risk of leakage caused by the bottom planar transistor being formed from the lower fin element 104L may be reduced. Therefore, the performance of the resulting semiconductor device may be enhanced, e.g., faster speed, lower power consumption, and/or lower off-state current.

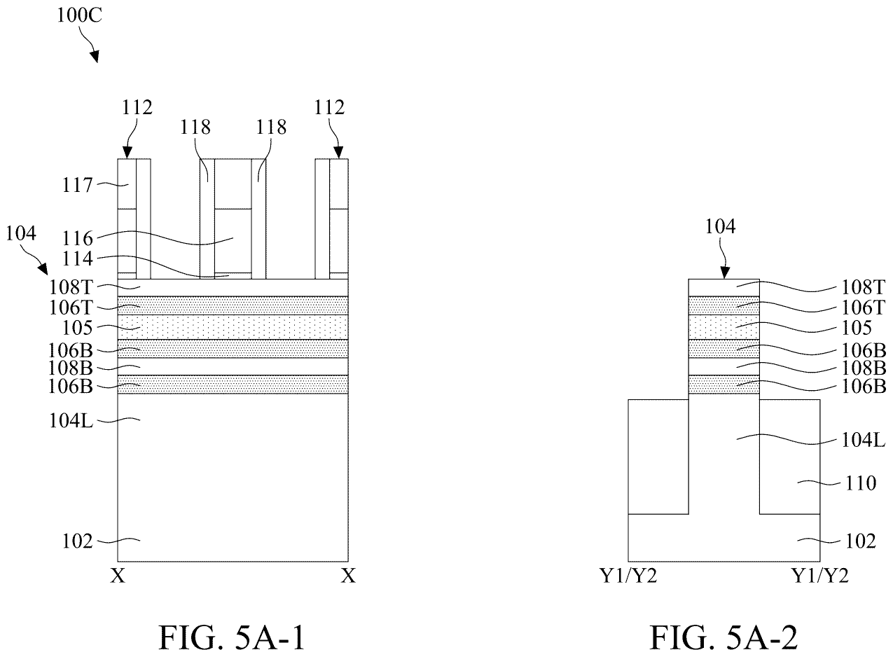

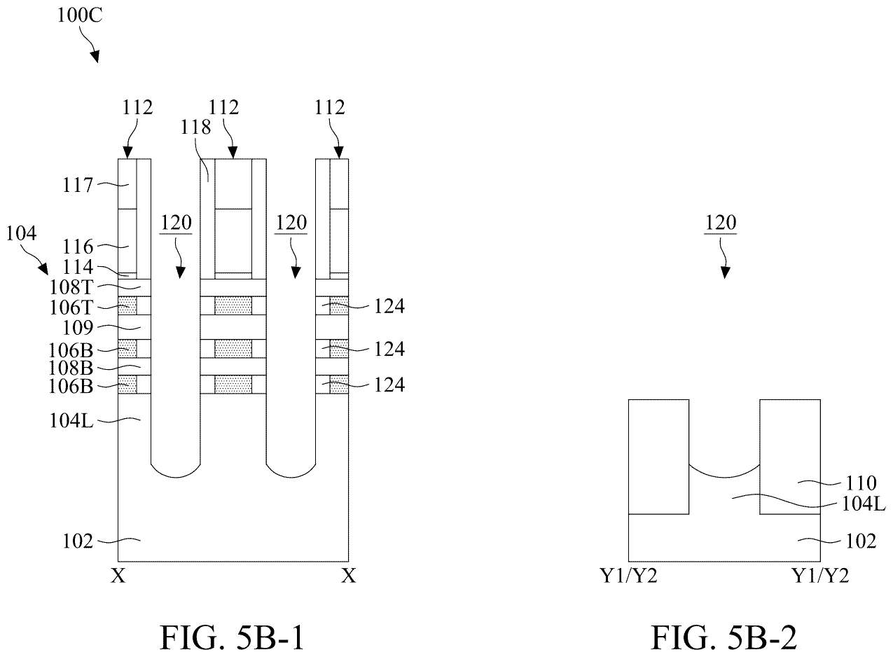

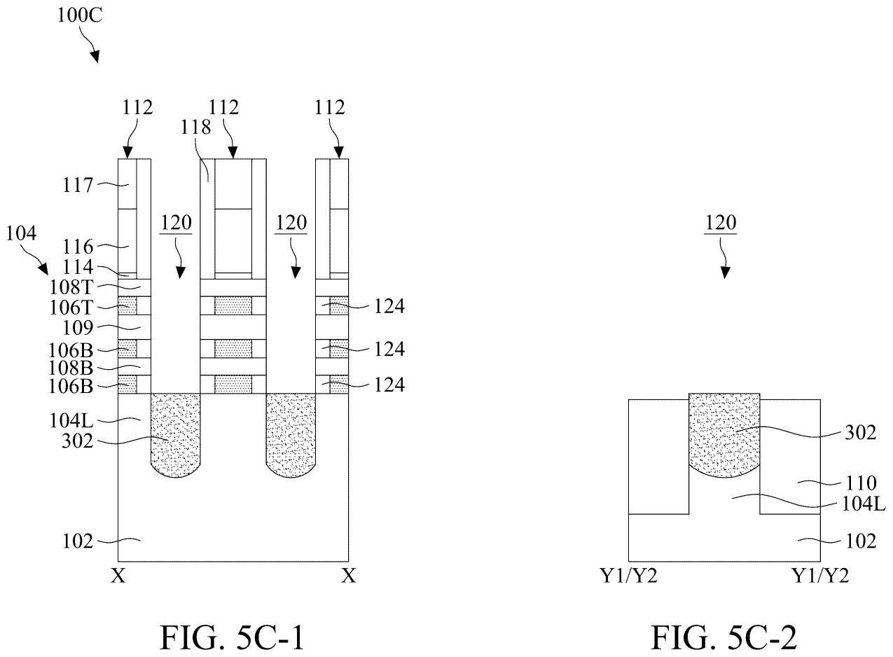

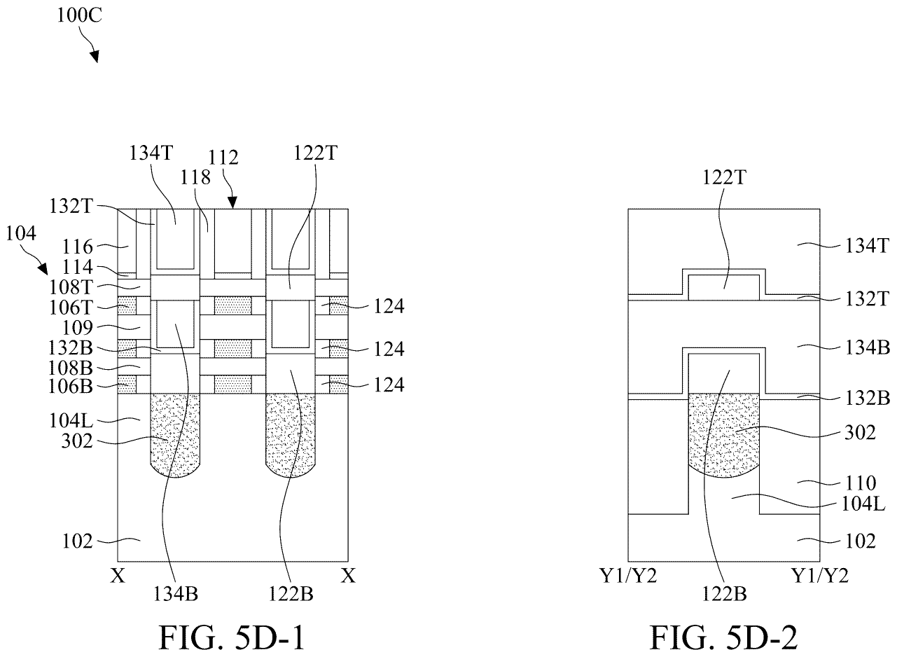

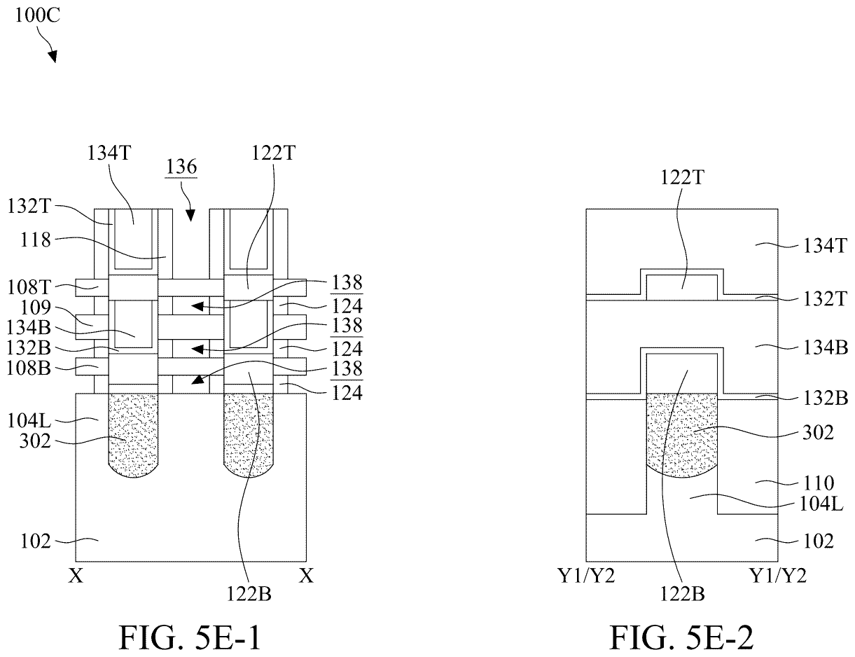

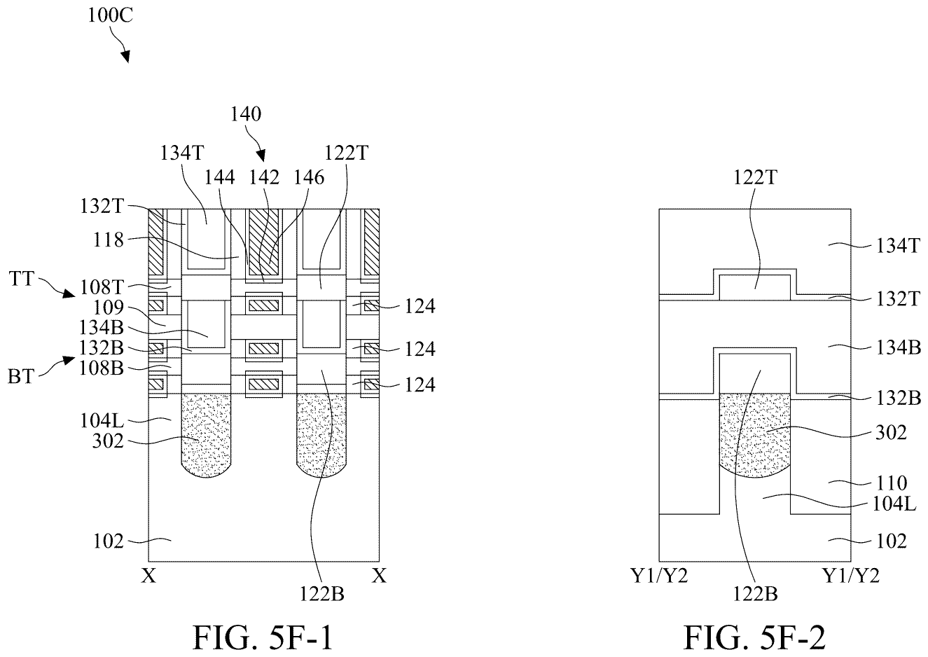

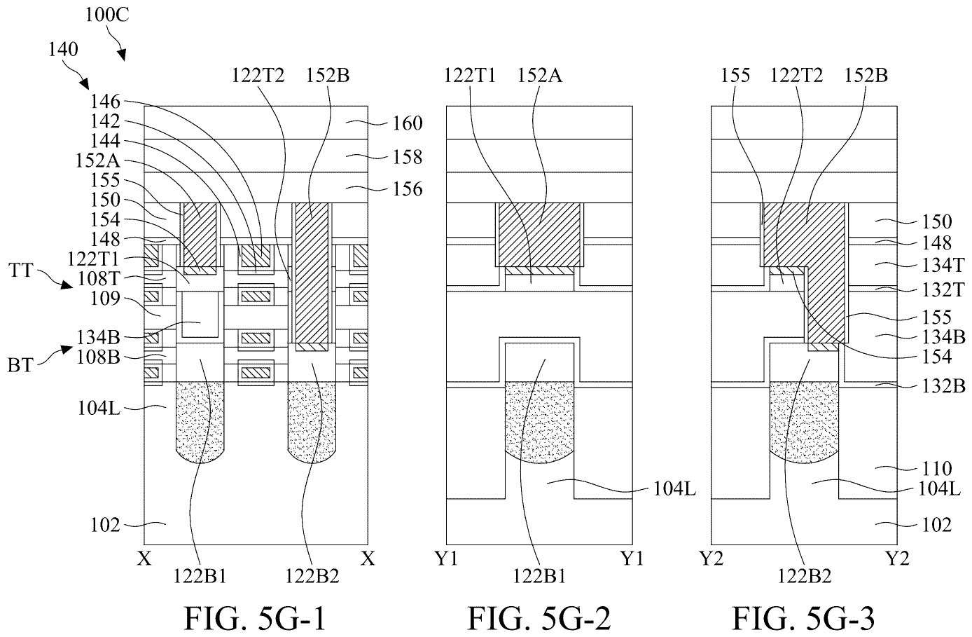

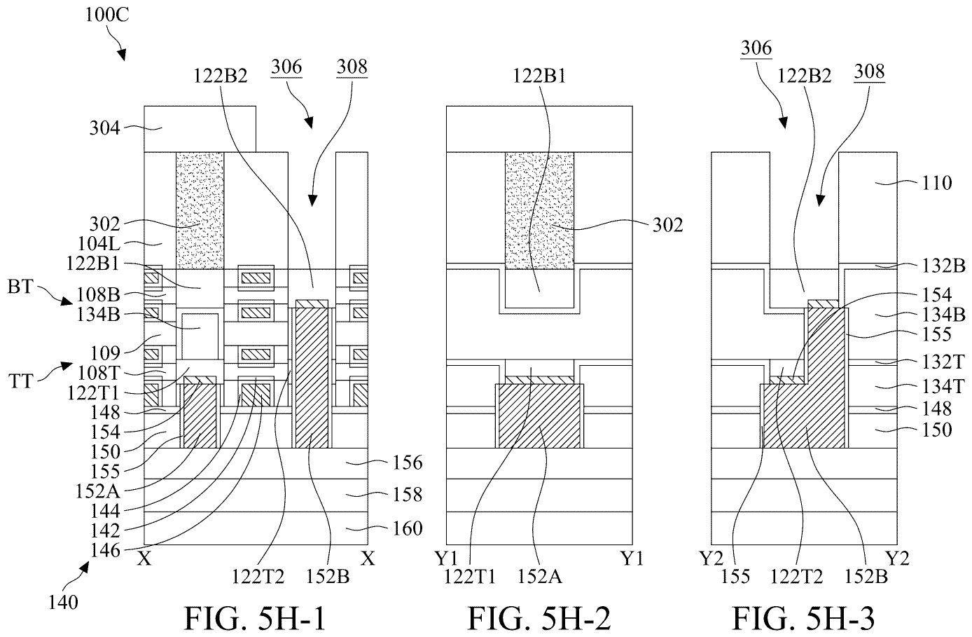

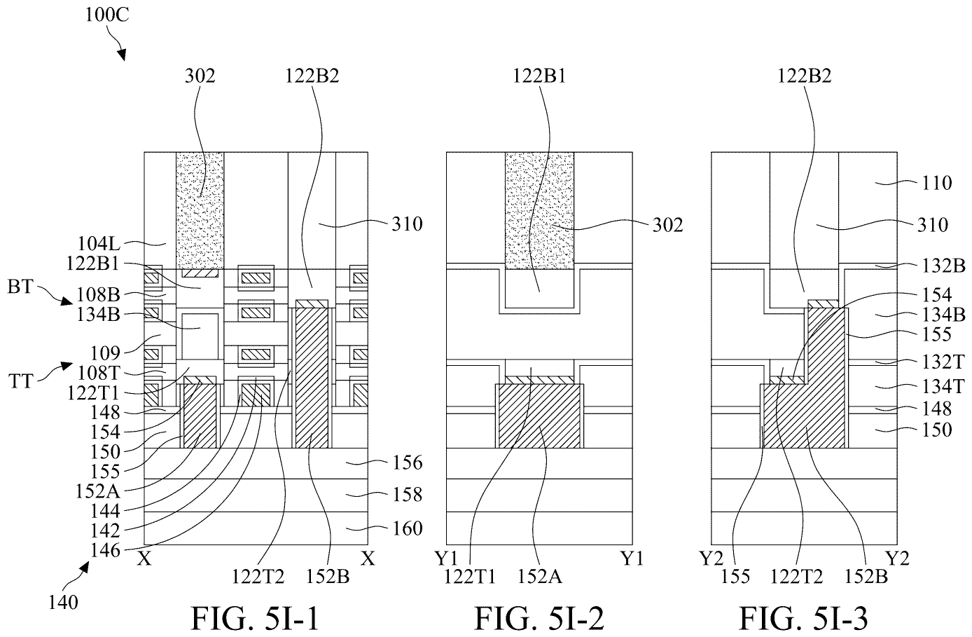

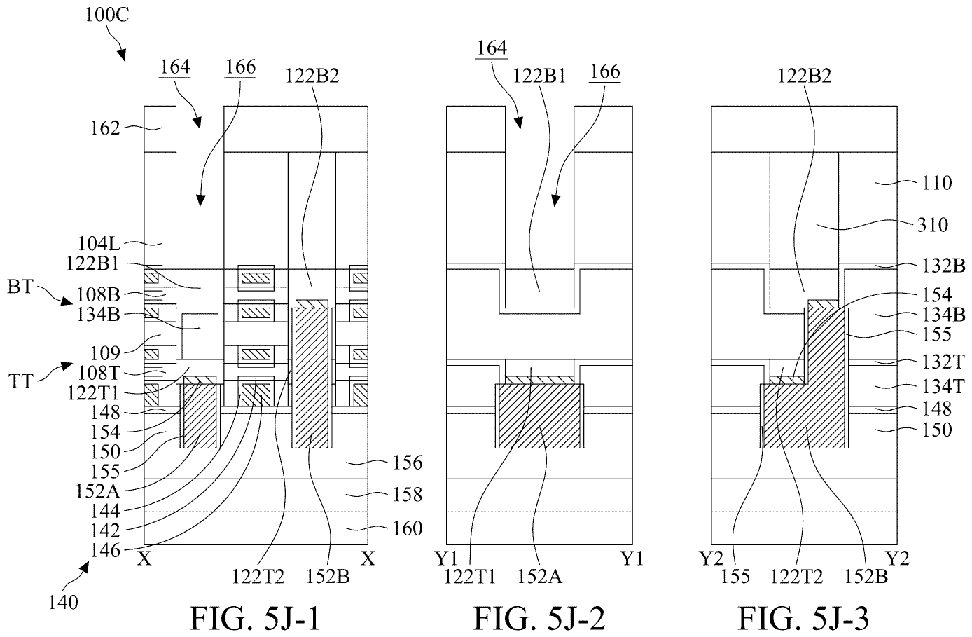

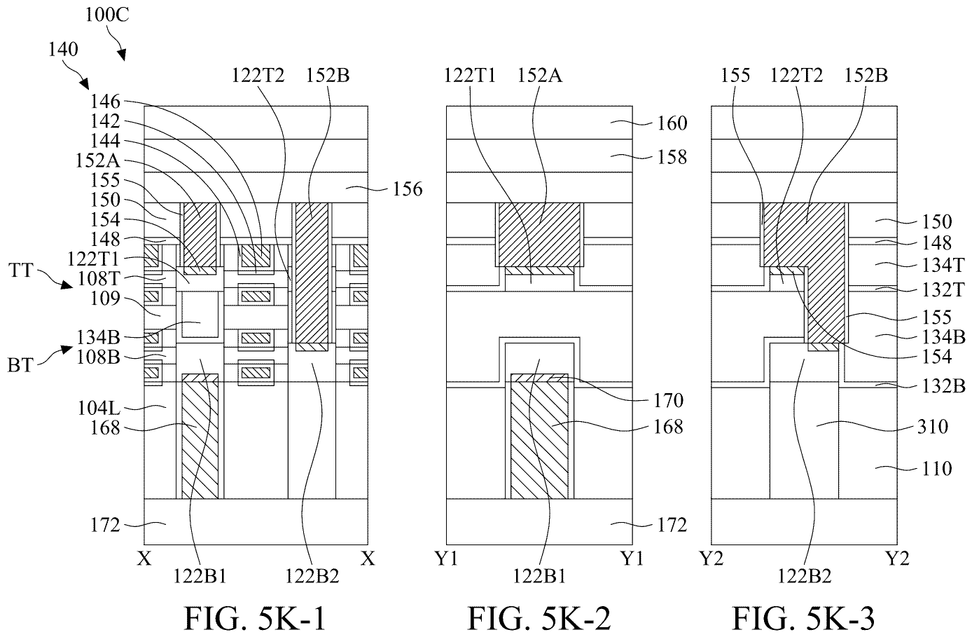

FIGS. 5A-1 through 5K-3 are cross-sectional views illustrating the formation of the semiconductor structure at various intermediate stages, in accordance with some embodiments of the disclosure. FIGS. 5A-1, 5B-1, 5C-1, 5D-1, 5E-1, 5F-1, 5G-1, 5H-1, 5I-1, 5J-1 and 5K-1 correspond to line X-X of FIG. 2. FIGS. 5A-2, 5B-2, 5C-2, 5D-2, 5E-2 and 5F-2 correspond to line Y 1 -Y1 or line Y 2 -Y2 of FIG. 2. FIGS. 5G-2, 5H-2, 5I-2, 5J-2 and 5K-2 correspond to line Y 1 -Y1 of FIG. 2. FIGS. 5G-3, 5H-3, 5I-3, 5J-3 and 5K-3 correspond to line Y2-Y2 of FIG. 2. The embodiments of FIGS. 5A-1 to 5K-3 are similar to the embodiments of FIGS. 3A-1 to 3K-3 except that the lower fin element 104L under the bottom source/drain feature 122B2 is replaced by a dielectric isolation feature 310.

A semiconductor structure 100C is provided, as shown in FIGS. 5A-1 and 5A-2, in accordance with some embodiments. The semiconductor structure 100C includes an active region 104 over the substrate 102, and an isolation structure 110 surrounding the lower fin element 104L of the active region 104, in accordance with some embodiments. Dummy gate structures 112 are formed across the active region 104 and the isolation structure 110, and gate spacer layers 118 are formed along opposite sidewalls of the dummy gate structures 112, in accordance with some embodiments.

An etching process is performed to recess the source/drain regions of the active region 104, thereby forming source/drain recesses 120, as shown in FIGS. 5B-1 and 5B-3, in accordance with some embodiments. The source/drain recesses 120 extend a distance into the lower fin element 104L, in accordance with some embodiments. In some embodiments, the distance between the bottom surfaces of the source/drain recesses 120 and the bottom surface of the isolation structure 110 is less than the distance between the bottom surfaces of the source/drain recesses 120 and the top surface of the isolation structure 110.

An etching process is performed to remove the middle layer 105, thereby forming a gap, and then an insulating layer 109 is formed in the gap, in accordance with some embodiments. An etching process is performed to laterally recess, from the source/drain recesses 120, the first semiconductor layers 106B and 106T of the active region 104, thereby forming notches, and then inner spacer layers 124 are formed in the notches, in accordance with some embodiments.

FIGS. 5C-1 and 5C-2 illustrate the semiconductor structure 100C after the formation of sacrificial features 302, in accordance with some embodiments.

Sacrificial features 302 are formed in the source/drain recesses 120 on the lower fin element 104L, as shown in FIGS. 5C-1 and 5C-2, in accordance with some embodiments. In some embodiments, the sacrificial features 302 are made of an epitaxial semiconductor material such as silicon germanium, formed by MBE, MOCVD, or VPE, another suitable technique, or a combination thereof. In some embodiments, the sacrificial features 302 are SiGe layers with a different germanium concentration than the following formed bottom source/drain features 122B. That is, the sacrificial features 302 and the bottom source/drain features 122B have a great difference in etching selectivity. In some embodiments, the top surfaces of the sacrificial features 302 are lower than the bottom surface of the second semiconductor layers 108B.

Bottom source/drain features 122B are grown from the exposed side surfaces of the second semiconductor layers 108B and the top surfaces of the sacrificial features 302 in the source/drain recesses 120, as shown in FIGS. 5D-1 and 5D-2, in accordance with some embodiments. In some embodiments, a non-doped silicon layer may be formed on the sacrificial features 302 before the bottom source/drain features 122B are grown. A contact etching stop layer 132B is formed to cover the bottom source/drain features 122B, and a first interlayer dielectric layer 134B is formed over the contact etching stop layer 132B, in accordance with some embodiments.

Top source/drain features 122T are grown from the exposed side surfaces of the second semiconductor layers 108T, as shown in FIGS. 5D-1 and 5D-2, in accordance with some embodiments. A contact etching stop layer 132T is formed to cover the top source/drain features 122T, and a first interlayer dielectric layer 134T is formed over the contact etching stop layer 132T, in accordance with some embodiments.

The dummy gate structures 112 are removed using an etching process to form gate trenches 136, and an etching process is performed on the first semiconductor layers 106B and 106T to form gaps 138, as shown in FIGS. 5E-1 and 5E-2, in accordance with some embodiments. The exposed second semiconductor layers 108B and 108T form nanostructures 108B and 108T, in accordance with some embodiments.

Final gate stacks 140 are formed in the gate trenches 136 and gaps 138, as shown in FIGS. 5F-1 and 5F-2, in accordance with some embodiments. The nanostructures 108B and 108T are wrapped by the final gate stacks 140, in accordance with some embodiments.

The bottom portion of the final gate stacks 140 that are wrapped around the bottom nanostructure 108B combine with the neighboring bottom source/drain features 122B to form a bottom transistor BT. The top portion of the final gate stacks 140 that are wrapped around the top nanostructure 108T combine with the neighboring top source/drain features 122T to form a top transistor TT. The n-channel top transistor TT is directly stacked above the p-channel bottom transistors BT thereby constructing a CFET, in accordance with some embodiments.

An etching stop layer 148 and a second interlayer dielectric layer 150 are sequentially formed over the semiconductor structure 100C, as shown in FIGS. 5G-1, 5G-2 and 5G-3, in accordance with some embodiments. A contact structure 152A is formed to land on the top source/drain feature 122T1, and a contact structure 152B is formed to land on the top source/drain features 122T2 and the bottom source/drain feature 122B2, in accordance with some embodiments.

A frontside interconnect structure 156 is formed over the semiconductor structure 100C, a bonding dielectric material 158 is formed over the frontside interconnect structure 156, and a carrier substrate 160 is bonded to the frontside surface of the semiconductor structure 100C, as shown in FIGS. 5G-1, 5G-2 and 5G-3, in accordance with some embodiments. The semiconductor structure 100C (or the semiconductor substrate 102) is flipped upside down, and the substrate 102 is removed from the backside of the semiconductor structure 100C, in accordance with some embodiments.

FIGS. 5H-1, 5H-2 and 5H-3 illustrate the semiconductor structure 100C after the formation of an opening 308, in accordance with some embodiments.

A patterned mask layer 304 is formed over the backside of the semiconductor structure 100C, as shown in FIGS. 5H-1, 5H-2 and 5H-3, in accordance with some embodiments. The patterned mask layer 304 has an opening pattern 306 corresponding (or being substantially aligned with) the bottom source/drain features 122B2, in accordance with some embodiments. The patterned mask layer 304 covers the bottom source/drain features 122B1, in accordance with some embodiments. The patterned mask layer 304 may be a patterned mask layer and/or a patterned photoresist layer. The formation of the patterned mask layer 304 may be similar to the formation of the patterned mask layer 162.

An etching process is performed using the patterned mask layer 304 to remove the sacrificial feature 302 which is exposed from the opening pattern 306, thereby forming an opening 306, as shown in FIGS. 5H-1, 5H-2 and 5H-3, in accordance with some embodiments. The etching process may include dry etching such as RIE, NBE, ICP etch, CCP etch, another suitable method, or a combination thereof. Afterward, the patterned mask layer 304 is removed using an etching process. The opening 306 exposes the backside surface (i.e., the top surfaces in the current schematics) of the bottom source/drain feature 122B2, in accordance with some embodiments.

FIGS. 5I-1, 5I-2 and 5I-3 illustrate the semiconductor structure 100C after the formation of a dielectric isolation feature 310, in accordance with some embodiments.

The dielectric isolation feature 310 is formed in the opening 308, as shown in FIGS. 5I-1 and 5I-3, in accordance with some embodiments. In some embodiments, the dielectric isolation feature 310 is made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof.

In some embodiments, the dielectric isolation feature 310 is formed by depositing a dielectric material to fill the opening 308, and then planarizing the dielectric material using such as CMP or an etching back process until the isolation structure 110 is exposed. The deposition process includes ALD, CVD (such as PECVD, LPCVD or HARP), another suitable technique, or a combination thereof.

In some embodiments, the dielectric isolation feature 310 is formed in a self-aligned manner in the location of the lower fin element 104, and thus the dielectric isolation feature 310 is confined within the area of the source/drain feature 122B2 in the top view. That is, the dielectric isolation feature 310 does not exceed the sidewalls of the source/drain feature 122B2 in the Y direction. In some embodiments, the dielectric isolation feature 310 is narrow than the source/drain features 122B2 in the Y direction. In some embodiments, the dielectric isolation feature 310 is narrow than the contact structure 152B in the Y direction.

A patterned mask layer 162 is formed over the backside of the semiconductor structure 100C, and an etching process is performed using the patterned mask layer 162 to remove the sacrificial feature 302 which are corresponding to the bottom source/drain feature 122B1, thereby forming a contact opening 166, as shown in FIGS. 5J-1, 5J-2 and 5J-3, in accordance with some embodiments.

A contact liner 167 is formed along the sidewalls of the contact opening 166, a silicide layer 170 is formed on the backside surface of the bottom source/drain feature 122B1, and a contact structure 168 is formed in the contact opening 166 to land on the backside surface of the bottom source/drain feature 122B1, as shown in FIGS. 5K-1 and 5K-2, in accordance with some embodiments. The backside interconnect structure 172 is formed over the backside of the semiconductor structure 100C, in accordance with some embodiments. In some embodiments, the bottom surface of the dielectric isolation feature 310 is substantially level with the bottom surface of the backside contact structure 168. In some embodiments where the bottom transistor BT is a p-channel FET, and the top transistor TT is an n-channel FET, the top source/drain features 122T1 of the top transistor TT is electrically connected to a Vss frontside power rail formed in a frontside first-level metal layer (M1), and the bottom source/drain feature 122B1 of the bottom transistor BT is electrically connected to a Vdd backside power rail formed in a backside first-level metal layer (BM1) through the backside contact structure 168.

In accordance with the embodiments of the present disclosure, a non-metallic structure (e.g., the dielectric isolation feature 310) is formed on the backside surface of the bottom source/drain feature 122B2 for the non-Vdd/Vss node of the bottom device, rather than a metallic structure being formed on the backside surface of the bottom source/drain feature 122B2. Because the portion of lower fin element 104L under the bottom source/drain feature 122B2 is replaced with the dielectric isolation feature 310, the parasitic capacitance of the bottom device BT may be further reduced, and thus the overall cell capacitance of the CFET device may be further reduced. In addition, the risk of leakage caused by the bottom planar transistor being formed from the lower fin element 104L may be reduced. Furthermore, the bottom source/drain feature 122B is formed on the sacrificial feature 302 instead of dielectric material, so that the amount of crystal defects (e.g., dislocations) formed within the bottom source/drain feature 122B may not significantly increase. Therefore, the performance of the resulting semiconductor device may be enhanced, e.g., faster speed, lower power consumption, and/or lower off-state current.

In addition, the backside contact structure 168 and the dielectric isolation features 310 are formed in a self-aligned manner in the location of the sacrificial features 302. As a result, the overlay window of the photolithography process for forming the backside contact structure 168 and the dielectric isolation features 310 may be enlarged. Therefore, the manufacturing yield of the resulting semiconductor device may be increased.

As described above, the semiconductor structure includes CFET devices, and each of the CFET devices includes a bottom transistor BT and a top transistor TT. The frontside surfaces of the source/drain features 122T1 and 122T2 of the top transistor TT are connected to the frontside contact structures 152A and 152B, and the backside surface of the source/drain feature 122B1 of the bottom transistor BT is connected to the backside contact structure 168. The source/drain feature 122B2 of the bottom transistor BT is connected to the frontside contact structure 152B. Because no contact structure is formed on the backside surface of the source/drain feature 122B2, the parasitic capacitance of the bottom device BT may be reduced, and thus the overall cell capacitance of the CFET device may be reduced. Therefore, the performance of the resulting semiconductor device may be enhanced, e.g., with faster speed and lower power consumption.

In addition, in some embodiments, a dielectric isolation feature 204 or 310 is formed between the source/drain feature 122B2 and the lower fin element 104L, the parasitic capacitance of the bottom device BT may be further reduced, and thus the overall cell capacitance of the CFET device may be further reduced.

Embodiments of a semiconductor structure and the method for forming the same may be provided. The method for forming a CET device includes a bottom transistor and a top transistor above the bottom transistor. The method further includes forming an opening exposing the backside surface of the first bottom source/drain feature for the source terminal while keeping a backside surface of the second bottom source/drain feature for the drain terminal unexposed. No contact structure is formed on the backside surface of the second bottom source/drain feature. Therefore, the performance of the resulting semiconductor device may be enhanced, e.g., with faster speed and lower power consumption.

In some embodiments, a method for forming a semiconductor structure is provided. The method includes forming a fin structure over a substrate. The fin structure includes a lower fin element, a bottom device region over the lower fin element and a top device region over the bottom device region, and each of the bottom device region and the top device region includes a first semiconductor layer and a second semiconductor layer on the first semiconductor layer. The method further includes forming a first bottom source/drain feature and a second bottom source/drain feature adjoining the bottom device region of the fin structure, and forming a first top source/drain feature and a second top source/drain feature adjoining the top device region of the fin structure. The method further includes etching a first portion of the lower fin element to form an opening exposing a backside surface of the first bottom source/drain feature while keeping a backside surface of the second bottom source/drain feature covered by a second portion of the lower fin element, and forming a backside contact structure in the opening.

In some embodiments, a method for forming a semiconductor structure is provided. The method includes forming a fin structure over a substrate. The fin structure includes a first channel layer, a second channel layer and a sacrificial layer vertically between the first channel layer and the second channel layer. The method further includes etching the fin structure to form a first source/drain recess and a second source/drain recess, forming a first sacrificial layer in the first source/drain recess and the second sacrificial layer in the second source/drain recess, and forming a first bottom source/drain feature and a second bottom source/drain feature adjoining the first channel layer. The method further includes forming a first top source/drain feature and a second top source/drain feature adjoining the second channel layer, forming a top contact structure on the first top source/drain feature, replacing the second sacrificial layer with a dielectric isolation feature, and replacing the first sacrificial layer with a bottom contact structure.

In some embodiments, a semiconductor structure is provided. The semiconductor structure includes a bottom transistor and a top transistor above the bottom transistor. The bottom transistor includes a first nanostructure, and a first bottom source/drain feature and a second bottom source/drain feature adjoining the first nanostructure. The top transistor includes a second nanostructure, and a first top source/drain feature and a second top source/drain feature adjoining the second nanostructure. The semiconductor structure further includes a first frontside contact structure on a top surface of the first top source/drain feature, a backside contact structure on a bottom surface of the first bottom source/drain feature, and a non-metallic structure on a bottom surface of the second bottom source/drain feature. The non-metallic structure has a different material composition than a material composition of the backside contact structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a fin structure over a substrate, wherein the fin structure includes a lower fin element, a bottom device region over the lower fin element and a top device region over the bottom device region, and each of the bottom device region and the top device region includes a first semiconductor layer and a second semiconductor layer on the first semiconductor layer;
forming a first bottom source/drain feature and a second bottom source/drain feature adjoining the bottom device region of the fin structure;
forming a first top source/drain feature and a second top source/drain feature adjoining the top device region of the fin structure;
etching a first portion of the lower fin element to form an opening exposing a backside surface of the first bottom source/drain feature while keeping a backside surface of the second bottom source/drain feature covered by a second portion of the lower fin element; and
forming a backside contact structure in the opening.

2. The method for forming the semiconductor structure as claimed in claim 1, further comprising:
etching the fin structure to form a first source/drain recess and a second source/drain recess;
forming a first dielectric isolation feature over a surface of the lower fin element exposed from the first source/drain recess; and
forming a second dielectric isolation feature over a surface of the lower fin element exposed from the second source/drain recess,
wherein the first bottom source/drain feature and the first top source/drain feature are formed in the first source/drain recess, and the second bottom source/drain feature and the second top source/drain feature are formed in the second source/drain recess.

3. The method for forming the semiconductor structure as claimed in claim 2, further comprising:
removing the first dielectric isolation feature while keeping the backside surface of the second bottom source/drain feature covered by the second dielectric isolation feature.

4. The method for forming the semiconductor structure as claimed in claim 3, further composing:
forming a first separation layer on the surface of the lower fin element exposed from the first source/drain recess; and
forming a second separation layer on the surface of the lower fin element exposed from the second source/drain recess,
wherein the first dielectric isolation feature is formed on the first separation layer, and the second dielectric isolation feature is formed on the second separation layer.

5. The method for forming the semiconductor structure as claimed in claim 1, wherein the first and second bottom source/drain features are doped with a p-type dopant, and the first and second top source/drain features are doped with an n-type dopant.

6. The method for forming the semiconductor structure as claimed in claim 1, further comprising:
removing the first semiconductor layers of the fin structure; and
forming a gate stack to surround the second semiconductor layers of the fin structure.

7. The method for forming the semiconductor structure as claimed in claim 1, wherein the fin structure further includes a middle layer between the bottom device region and the top device region, and the middle layer is made of a semiconductor material, and the method further comprises, before forming the gate stack:
removing the middle layer to form a gap; and
forming an insulating layer in the gap.

8. The method for forming the semiconductor structure as claimed in claim 7, further comprising:
flipping the substrate upside down;
removing the substrate; and
forming a patterned mask layer over the lower fin element, wherein the patterned mask layer has an opening aligned with the first bottom source/drain feature.

9. The method for forming the semiconductor structure as claimed in claim 1, further comprising:
forming a first frontside contact structure on the first top source/drain feature; and
forming a second frontside contact structure through the second top source/drain feature and on the second bottom source/drain feature.

10. A method for forming a semiconductor structure, comprising:
forming a fin structure over a substrate, wherein the fin structure includes a first channel layer, a second channel layer and a sacrificial layer vertically between the first channel layer and the second channel layer;
etching the fin structure to form a first source/drain recess and a second source/drain recess;
forming a first sacrificial feature in the first source/drain recess and the second sacrificial feature in the second source/drain recess;
forming a first bottom source/drain feature and a second bottom source/drain feature adjoining the first channel layer;
forming a first top source/drain feature and a second top source/drain feature adjoining the second channel layer;
forming a top contact structure on the first top source/drain feature;
replacing the second sacrificial feature with a dielectric isolation feature; and
replacing the first sacrificial feature with a bottom contact structure.

11. The method for forming the semiconductor structure as claimed in claim 10, further comprising:
forming an interlayer dielectric layer to cover the first bottom source/drain feature and the second bottom source/drain feature before forming the first top source/drain feature and the second top source/drain feature on the second channel layer.

12. The method for forming the semiconductor structure as claimed in claim 10, wherein the fin structure further includes a lower fin element under the first channel layer, and the first source/drain recess and the second source/drain recess extend into the lower fin element.

13. The method for forming the semiconductor structure as claimed in claim 10, further comprising:
forming a Vss power rail electrically connected to the top contact structure; and
forming a Vdd power rail electrically connected to the bottom contact structure.

14. The method for forming the semiconductor structure as claimed in claim 10, wherein the first sacrificial layer and the second sacrificial layer are made of SiGe.

15. A semiconductor structure, comprising:
a bottom transistor comprising a first nanostructure, and a first bottom source/drain feature and a second bottom source/drain feature adjoining the first nanostructure;
a top transistor above the bottom transistor, the top transistor comprising a second nanostructure, and a first top source/drain feature and a second top source/drain feature adjoining the second nanostructure;
a first frontside contact structure on a top surface of the first top source/drain feature;
a backside contact structure on a bottom surface of the first bottom source/drain feature; and
a non-metallic structure on a bottom surface of the second bottom source/drain feature, wherein the non-metallic structure has a different material composition than a material composition of the backside contact structure.

16. The semiconductor structure as claimed in claim 15, wherein the non-metallic structure is made of a semiconductor material or a dielectric material.

17. The semiconductor structure as claimed in claim 15, wherein a bottom surface of the non-metallic structure is level with a bottom surface of the backside contact structure.

18. The semiconductor structure as claimed in claim 15, wherein a bottom surface of the non-metallic structure is higher than a bottom surface of the backside contact structure.

19. The semiconductor structure as claimed in claim 15, further comprising:
a fin element under the non-metallic structure, wherein a bottom surface of the fin element is level with a bottom surface of the backside contact structure.

20. The semiconductor structure as claimed in claim 15, further comprising:
a second frontside contact structure on a top surface of the second top source/drain feature; and
an interlayer dielectric layer between the first bottom source/drain feature and the first top source/drain feature and between the second bottom source/drain feature and the second top source/drain feature, wherein the second frontside contact structure penetrates through the second top source/drain feature and the interlayer dielectric layer to land on the second bottom source/drain feature.
